(19) United States
(12) Patent Application Publication
(10) Pub. No.: US 2023/0171993 A1
(43) Pub. Date: Jun. 1, 2023

(54) DISPLAY PANEL, DISPLAY APPARATUS INCLUDING THE SAME AND METHOD FOR FABRICATING THE SAME

(71) Applicant: SAMSUNG DISPLAY CO., LTD, Yongin-si (KR)

(72) Inventors: Su Jeong KIM, Seoul (KR); Dae Won KIM, Hwaseong-si (KR); Jong Ho SON, Seoul (KR); Jin Hyeong LEE, Suwon-si (KR); Ji Yoon JUNG, Asan-si (KR); Young Seo CHOI, Yongin-si (KR)

(21) Appl. No.: 17/854,263

(22) Filed: Jun. 30, 2022

(30) Foreign Application Priority Data
Dec. 1, 2021 (KR) 10-2021-0170462

(51) Int. Cl. H01L 51/52; H01L 27/32; G06F 3/044; H01L 51/56

(52) U.S. Cl. CPC H01L 51/5284; H01L 51/5271; H01L 27/3246; H01L 27/323; H01L 51/524; G06F 3/0446; H01L 51/56; H01L 2227/323

(57) ABSTRACT

A display panel includes a support substrate including a display area having a plurality of pixel areas and a non-display area disposed around the display area. An encapsulation substrate faces a first side of the support substrate. An emitting array is disposed on the first side of the support substrate. A phase adjusting layer is disposed on the emitting array and changes a phase of light. A reflected light absorbing layer is disposed on the phase adjusting layer and absorbs at least a portion of light reflected from the emitting array. A sealing layer is disposed in the non-display area between the support substrate and the encapsulation substrate. A black matrix layer is disposed on a first side of the encapsulation substrate and corresponds to boundaries between the plurality of pixel areas.

### CROSS-REFERENCE TO RELATED APPLICATION

This application claims priority under 35 U.S.C. § 119 to Korean Patent Application No. 10-2021-0170462, filed on Dec. 1, 2021 in the Korean Intellectual Property Office, the disclosure of which is incorporated by reference in its entirety herein.

### 1. TECHNICAL FIELD

The present disclosure relates to a display panel, a display apparatus including the same, and a method for fabricating the same.

### 2. DISCUSSION OF RELATED ART

The demand for display apparatuses for displaying images has increased and diversified as the information society has developed. For example, display apparatuses have been applied to various electronic devices such as smartphones, digital cameras, laptop computers, navigation devices, and smart televisions.

The display apparatus includes a display panel emitting light for displaying an image, and drivers supplying signals and voltages for driving the display panel.

The display panel may include a pair of substrates facing each other and a polarizing member or a light emitting member disposed between the pair of substrates.

In addition, the display apparatus may further include a polarizing plate disposed on a surface from which the light for displaying the image is emitted for reduction of outside light reflection.

Since the polarizing plate selectively transmits light polarized in a predetermined direction, outside light reflected by the display panel may be blocked from being emitted to the outside.

However, since the light for image display as well as the outside light is polarized by the polarizing plate, transmittance of the light for image display is decreased. Accordingly, light efficiency of the display apparatus is decreased, and there is a limitation in increasing luminance of the display apparatus.

### SUMMARY

Aspects of the present disclosure provide a display panel capable of reducing outside light reflection without including a polarizing plate, a display apparatus including the same, and a method for fabricating the same.

According to an embodiment of the present inventive concept, a display panel includes a support substrate including a display area having a plurality of pixel areas for displaying an image and a non-display area disposed around the display area. An encapsulation substrate faces a first side of the support substrate. An emitting array is disposed on the first side of the support substrate. The emitting array includes a plurality of emitting devices corresponding to the plurality of pixel areas. A phase adjusting layer is disposed on the emitting array. The phase adjusting layer changes a phase of light. A reflected light absorbing layer is disposed on the phase adjusting layer. The reflected light absorbing layer absorbs at least a portion of light reflected from the emitting array. A sealing layer is disposed in the non-display area between the support substrate and the encapsulation substrate. The sealing layer bonds the support substrate and the encapsulation substrate to each other. A black matrix layer is disposed on a first side of the encapsulation substrate facing the support substrate and corresponds to non-emission areas that are boundaries between the plurality of pixel areas.

In an embodiment, the phase adjusting layer delays the phase of light by λ/4. A first portion of outside light incident from the encapsulation substrate passes through the reflected light absorbing layer and the phase adjusting layer, and is reflected by the emitting array to become reflected light passing through the phase adjusting layer again and directed towards the encapsulation substrate. The reflected light and the outside light have opposite phases to each other. The reflected light absorbing layer absorbs at least a portion of the reflected light based on destructive interference between the reflected light and the outside light.

In an embodiment, the reflected light absorbing layer is made of an inorganic material having a refractive index greater than or equal to about 1 and an absorption coefficient greater than or equal to about 0.5.

In an embodiment, the reflected light absorbing layer is composed of at least one compound selected from bismuth (Bi) and ytterbium (Yb).

In an embodiment, the display panel further comprises a reflection adjusting layer disposed on the first side of the encapsulation substrate, the reflection adjusting layer covers the black matrix layer and absorbs a second portion of the outside light that is different from the first portion of the outside light.

In an embodiment, the reflection adjusting layer is composed of an organic material including a dye or a pigment.

In an embodiment, a minimum absorption wavelength region of the dye or the pigment is a wavelength region in a range of about 490 nm to about 505 nm or a wavelength region in a range of about 585 nm to about 600 nm.

In an embodiment, the display panel further comprises a sealing structure disposed on the reflected light absorbing layer.

In an embodiment, the sealing structure and the reflection adjusting layer are spaced apart from each other. The display panel further comprises a filling layer filling a space between the sealing structure and the reflection adjusting layer.

In an embodiment, the emitting array includes a plurality of first electrodes corresponding to the plurality of pixel areas, a pixel defining layer corresponding to the non-emission areas and covering edges of each of the plurality of first electrodes, a plurality of emitting structures disposed on the plurality of first electrodes, respectively, and a second electrode disposed on the pixel defining layer and the plurality of emitting structures. Each of the plurality of emitting devices has a structure in which each of the plurality of emitting structures is interposed between each of the plurality of first electrodes and the second electrode. The phase adjusting layer is disposed on the second electrode.

In an embodiment, the display panel further comprises an auxiliary sealing pattern disposed on a portion of a flank side of the sealing layer exposed to the outside.

In an embodiment, the auxiliary sealing pattern is formed of a hardened positive photoresist.

According to an embodiment of the present inventive concept, a display apparatus includes a display panel including a display area having a plurality of pixel areas for displaying an image. A touch sensing unit is disposed on the display panel. A protection substrate is attached to the display panel through an adhesive layer covering the touch sensing unit. The display panel includes a support substrate including the display area and a non-display area disposed around the display area. An encapsulation substrate faces a first side of the support substrate. An emitting array is disposed on the first side of the support substrate. The emitting array includes a plurality of emitting devices corresponding to the plurality of pixel areas. A phase adjusting layer is disposed on the emitting array. The phase adjusting layer changes a phase of light. A reflected light absorbing layer is disposed on the phase adjusting layer. The reflected light absorbing layer absorbs at least a portion of light reflected from the emitting array. A sealing layer is disposed in the non-display area between the support substrate and the encapsulation substrate. The sealing layer bonds the support substrate and the encapsulation substrate to each other. A black matrix layer is disposed on a first side of the encapsulation substrate facing the support substrate and corresponds to non-emission areas that are boundaries between the plurality of pixel areas in the display area. A reflection adjusting layer is disposed on the first side of the encapsulation substrate. The reflection adjusting layer covers the black matrix layer and absorbs at least a portion of outside light incident from the encapsulation substrate.

In an embodiment, the phase adjusting layer delays the phase of light by λ/4. A first portion of the outside light incident from the encapsulation substrate passes through the reflected light absorbing layer and the phase adjusting layer, and is reflected by the emitting array to become reflected light passing through the phase adjusting layer again and directed towards the encapsulation substrate. The reflected light and the outside light have opposite phases to each other. The reflected light absorbing layer absorbs at least a portion of the reflected light based on destructive interference between the reflected light and the outside light.

In an embodiment, the reflected light absorbing layer is made of an inorganic material having a refractive index greater than or equal to about 1 and an absorption coefficient greater than or equal to about 0.5.

In an embodiment, the reflected light absorbing layer is composed of at least one compound selected from bismuth (Bi) and ytterbium (Yb).

In an embodiment, the reflection adjusting layer is composed of an organic material including a dye or a pigment. A minimum absorption wavelength region of the dye or the pigment is a wavelength region in a range of about 490 nm to about 505 nm or a wavelength region in a range of about 585 nm to about 600 nm.

In an embodiment, the display panel further includes a sealing structure disposed on the reflected light absorbing layer.

In an embodiment, the sealing structure and the reflection adjusting layer are spaced apart from each other. The display panel further includes a filling layer filling a space between the sealing structure and the reflection adjusting layer.

In an embodiment, the display panel further includes an auxiliary sealing pattern disposed on a portion of a flank side of the sealing layer exposed to the outside.

In an embodiment, the auxiliary sealing pattern is formed of a hardened positive photoresist.

In an embodiment, the touch sensing unit is disposed on a second side of the encapsulation substrate opposite to the first side of the encapsulation substrate. The touch sensing unit includes a plurality of first touch lines extending in a first direction and a plurality of second touch lines extending in a second direction crossing the first direction. Each of the plurality of first touch lines includes first electrode patterns arranged in the first direction. Each of the plurality of second touch lines includes second electrode patterns disposed on a same layer as the first electrode patterns and arranged in the second direction and a contact pattern connecting between the second electrode patterns adjacent to each other in the second direction. Each of the plurality of first touch lines further includes a bridge pattern disposed on a different layer from the first and second electrode patterns. The bridge pattern crosses the contact pattern, and connect between the first electrode patterns adjacent to each other in the first direction.

According to an embodiment of the present inventive concept, a method for fabricating a display panel includes disposing an emitting array on a first side of a support substrate. The emitting array includes a plurality of emitting devices corresponding to a plurality of pixel areas for displaying an image. The support substrate includes a display area having the plurality of pixel areas arranged therein and a non-display area disposed around the display area. A phase adjusting layer is disposed on the emitting array. The phase adjusting layer changes a phase of light. A reflected light absorbing layer is disposed on the phase adjusting layer. The reflected light absorbing layer absorbs at least a portion of light reflected from the emitting array. A sealing layer is disposed on a first side of an encapsulation substrate including at least the display area. The sealing layer surrounds a periphery of the display area. A protection pattern is disposed covering the sealing layer. A black matrix layer is disposed on the first side of the encapsulation substrate. The black matrix layer corresponds to non-emission areas that are boundaries between the plurality of pixel areas in the display area. A reflection adjusting layer is disposed on the first side of the encapsulation substrate. The reflection adjusting layer covers the black matrix layer and absorbs at least a portion of outside light incident from the encapsulation substrate. At least a portion of the protection pattern is removed. The support substrate and the encapsulation substrate are aligned with each other so that the first side of the support substrate and the first side of the encapsulation substrate face each other. The support substrate and the encapsulation substrate are bonded to each other through the sealing layer.

In an embodiment, in the disposing of the protection pattern, the protection pattern is formed of a positive photoresist, and the removing of at least a portion of the protection pattern includes entirely irradiating the first side of the encapsulation substrate with light and developing the protection pattern.

In an embodiment, the removing of at least a portion of the protection pattern further includes, before entirely irradiating the first side of the encapsulation substrate with the light, a light shield mask is disposed which includes a light blocking area corresponding to a portion of a flank side of the sealing layer exposed to the outside, and in the developing of the protection pattern, a portion of the protection pattern corresponding to the light shield mask remains to form an auxiliary sealing pattern disposed on the portion of the flank side of the sealing layer exposed to the outside.

In an embodiment, the disposing of the sealing layer includes patterning a sealing material on the first side of the encapsulation substrate, and firing the sealing material in a high temperature environment greater than or equal to about 370° C. to prepare the sealing layer.

In an embodiment, in the disposing of the reflected light absorbing layer, the reflected light absorbing layer is composed of an inorganic material having a refractive index greater than or equal to about 1 and an absorption coefficient greater than or equal to about 0.5.

In an embodiment, the reflected light absorbing layer is composed of at least one compound selected from bismuth (Bi) and ytterbium (Yb).

In an embodiment, in the disposing of the reflection adjusting layer, the reflection adjusting layer is composed of an organic material including a dye or a pigment, and a minimum absorption wavelength region of the dye or the pigment is a wavelength region in a range of about 490 nm to about 505 nm or a wavelength region in a range of about 585 nm to about 600 nm.

A display panel according to an embodiment includes a phase adjusting layer disposed on an emitting array, a reflected light absorbing layer disposed on the phase adjusting layer and absorbing at least a portion of light reflected from the emitting array, and a black matrix layer disposed on one side of the encapsulation substrate and corresponding to boundaries between a plurality of pixel areas.

Accordingly, reflected light reflected from the emitting array has an opposite phase to outside light by the phase adjusting layer, and thus, the reflected light absorbing layer absorbs at least a portion of the reflected light by induction of destructive interference between the reflected light and the outside light, such that a phenomenon in which the outside light is reflected by the emitting array and is emitted through the encapsulation substrate, that is, outside light reflection may be reduced.

In addition, emission of light from the boundaries between the plurality of pixel areas may be blocked by the black matrix layer.

In addition, the display panel according to embodiments of the present inventive concept may further include a reflection adjusting layer disposed on one side of the encapsulation substrate and covering the black matrix layer. The reflection adjusting layer includes a dye or a pigment selectively absorbing light of a wavelength region that is not emitted from the plurality of pixel areas among the outside light incident through the encapsulation substrate, and thus, light efficiency may be increased while the outside light reflection is reduced.

Therefore, the display panel according to an embodiment may reduce the outside light reflection without including a polarizing plate, and thus, a decrease in light efficiency due to the polarizing plate may be prevented.

In addition, a method for fabricating a display panel according to an embodiment includes disposing a sealing layer on one side of an encapsulation substrate, disposing a protection pattern covering the sealing layer, and disposing a black matrix layer. That is, after the black matrix layer and the like are disposed in a state in which the sealing layer is covered with the protection pattern, the sealing layer and the black matrix layer may be disposed on one side of the encapsulation substrate by a process of removing the protection pattern.

In this embodiment, the sealing layer is disposed before the black matrix layer are disposed, and thus, a sealing layer made of a sealing material fired in a high-temperature environment may be prepared. In addition, since the black matrix layer are disposed in the state in which the sealing layer is covered with the protection pattern, a foreign material made of a material of the black matrix layer may be removed together with the protection pattern when the protection pattern is removed, and thus, the foreign material may be prevented from remaining on the sealing layer.

Accordingly, it is possible to prevent a decrease in adhesive force of the sealing layer while disposing the sealing layer and the black matrix layer on one side of the encapsulation substrate.

However, the effects of embodiments of the present inventive concept are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display apparatus according to an embodiment of the present disclosure;

FIG. 2 is a plan view illustrating the display apparatus of FIG. 1 according to an embodiment of the present disclosure;

FIG. 3 is a cross-sectional view of the display apparatus taken along I-I′ of FIG. 2 according to an embodiment of the present disclosure;

FIG. 4 is a plan view illustrating a touch sensing unit of FIG. 3 according to an embodiment of the present disclosure;

FIG. 5 is an enlarged view of the touch sensing unit illustrating portion III of FIG. 4 according to an embodiment of the present disclosure;

FIG. 6 is a cross-sectional view of the touch sensing unit taken along line IV-IV′ of FIG. 5 according to an embodiment of the present disclosure;

FIG. 7 is a plan view illustrating an example of a display panel of FIG. 3 according to an embodiment of the present disclosure;

FIG. 8 is an equivalent circuit diagram illustrating a pixel driving circuit corresponding to any one pixel area of FIG. 7 according to an embodiment of the present disclosure;

FIG. 9 is a cross-sectional view illustrating an example of a driving transistor and an emitting device of FIG. 8 according to an embodiment of the present disclosure;

FIG. 10 is an enlarged view of the display apparatus illustrating portion 11 of FIG. 3 according to a first embodiment;

FIG. 11 is an enlarged view of the display apparatus illustrating portion II of FIG. 3 according to a second embodiment;

FIG. 12 is an enlarged view of the display apparatus illustrating portion II of FIG. 3 according to a third embodiment;

FIG. 13 is a cross-sectional view of the display apparatus taken along line I-I′ of FIG. 2 according to a fourth embodiment;

FIG. 14 is a cross-sectional view of the display apparatus taken along line I-I′ of FIG. 2 according to a fifth embodiment;

FIG. 15 is a flowchart illustrating a method for fabricating a display panel according to an embodiment of the present disclosure;

FIGS. 16 to 27 are cross-sectional views illustrating processes for each step of a method of FIG. 15 according to embodiments of the present disclosure;

FIG. 28 is a cross-sectional view illustrating some processes of a method for fabricating a display panel illustrated in FIG. 12 according to an embodiment of the present disclosure; and

FIG. 29 is a cross-sectional view illustrating some processes of a method for fabricating a display panel illustrated in FIG. 14 according to an embodiment of the present disclosure.

### DETAILED DESCRIPTION OF EMBODIMENTS

Embodiments will now be described more fully hereinafter with reference to the accompanying drawings. Embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided to describe embodiments of the present disclosure for convenience of explanation.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower.” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

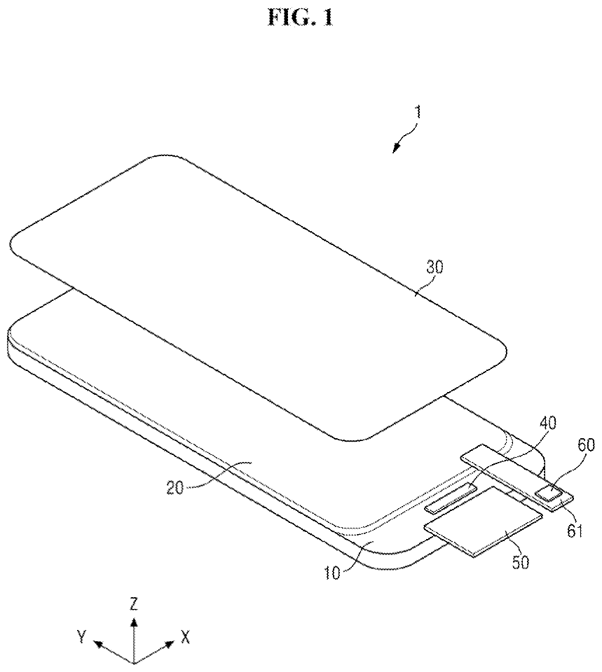

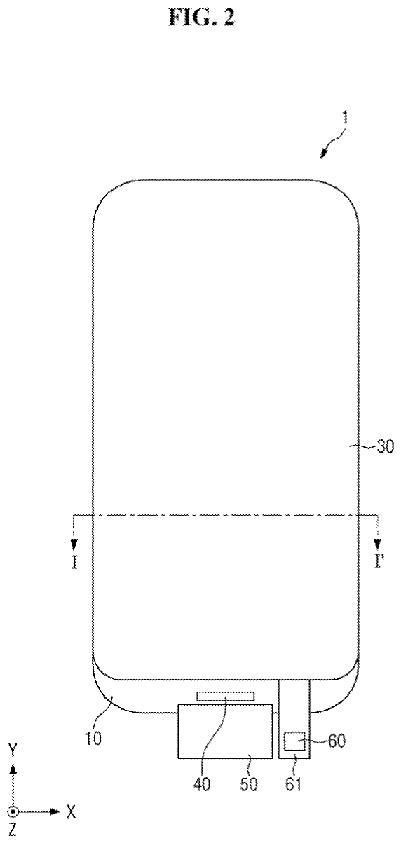

FIG. 1 is a perspective view illustrating a display apparatus according to an embodiment. FIG. 2 is a plan view illustrating the display apparatus of FIG. 1.

Referring to FIGS. 1 and 2, a display apparatus 1 is an apparatus that displays at least one moving image and/or still image, and may be used as a display screen of each of various products such as televisions, laptop computers, monitors, billboards, and Internet of Things (IOT) as well as portable electronic devices such as mobile phones, smartphones, tablet personal computers (PCs), smartwatches, watch phones, mobile communication terminals, electronic organizers, electronic books, portable multimedia players (PMPs), navigation devices, and ultra mobile PCs (UMPCs). However, embodiments of the present disclosure are not necessarily limited thereto.

The display apparatus 1 may be any one of an organic light emitting display apparatus, a liquid crystal display apparatus, a plasma display apparatus, a field emission display apparatus, an electrophoretic display apparatus, an electro-wetting display apparatus, a quantum dot light emitting display apparatus, a micro light emitting diode (LED) display apparatus, and the like. Hereinafter, it has been mainly described that the display apparatus 1 is an organic light emitting display apparatus, but embodiments of the present disclosure are not necessarily limited thereto.

The display apparatus 1 according to an embodiment includes a display panel 10 emitting light for image display.

The display apparatus 1 may further include a protection substrate 30 disposed on the display panel 10 and protecting the display panel 10 from external physical and electrical shocks.

The display apparatus 1 may further include a display driving circuit 40 and a display circuit board 50 for driving the display panel 10.

In addition, the display apparatus 1 may further include a touch sensing unit 20 disposed on the display panel 10 and detecting coordinates of a point where an input, such as a user's touch, is performed in a display area from which light for image display is emitted.

In this embodiment, the display apparatus 1 may further include a touch driving circuit 60 and a touch circuit board 61 for driving the touch sensing unit 20.

The display panel 10 may have a structure including a pair of substrates facing each other and an emitting material or a polarizing material disposed between the pair of substrates.

The display panel 10 includes a display area in which a plurality of pixel areas emitting light for image display are arranged, and a non-display area, which is a peripheral area of the display area. The display panel 10 may further include display electrode pads disposed in the non-display area and electrically connected to the display circuit board 50.

The display area of the display panel 10 may have a rectangular shape having long sides in a first direction (Y-axis direction) and short sides in a second direction (X-axis direction) crossing the first direction (Y-axis direction). However, this is only an example, and the display area of the display panel 10 may be implemented in various forms.

As an example, the display area may have a shape in which a corner where the long side in the first direction (Y-axis direction) and the short side in the second direction (X-axis direction) meet is rounded with a predetermined curvature. Alternatively, the display area may have a shape such as a polygonal shape, a circular shape, and an elliptical shape. However, embodiments of the present disclosure are not necessarily limited thereto.

It has been illustrated in FIGS. 1 and 2 that the display panel 10 has a flat panel shape, but embodiments of the present disclosure are not necessarily limited thereto. For example, the display panel 10 may be made of a flexible material to have a shape in which at least a portion thereof is bent, folded, or rolled. As an example, the display panel 10 may have a shape in which both ends thereof in the Y-axis direction are bent.

The touch sensing unit 20 may include touch lines for detecting coordinates of a point touched by a user in the display area and touch electrode pads disposed in the non-display area and connected to the touch lines.

The touch sensing unit 20 may have a shape corresponding to that of the display area of the display panel 10 in a plan view. Alternatively, the touch sensing unit 20 may be provided in a shape different from that of the display panel 10 in a plan view. Such a shape of the touch sensing unit 20 in a plan view may be a polygonal shape such as a quadrangular shape or a hexagonal shape, a circular shape, or an elliptical shape. However, embodiments of the present disclosure are not necessarily limited thereto.

The touch sensing unit 20 may have a flat plate shape. Alternatively, the touch sensing unit 20 may have a shape in which it includes curved portions disposed at both ends thereof in the Y-axis direction. For example, the touch sensing unit 20 may be made of a flexible material to have the same deformed shape as the display panel 10.

As illustrated in FIG. 1, the touch sensing unit 20 may be disposed between the display panel 10 and the protection substrate 30. Alternatively, the touch sensing unit 20 may be embedded in the display panel 10 or may be disposed on the protection substrate 30.

The protection substrate 30 may be disposed on the display panel 10, and may be attached to the display panel 10 through an adhesive layer covering the touch sensing unit 20.

In an embodiment in which the touch sensing unit 20 is embedded in the display panel 10 or disposed on the protection substrate 30, an adhesive layer between the display panel 10 and the protection substrate 30 may be entirely adhered to an upper portion of the display panel 10.

The protection substrate 30 covers at least the display area of the display panel 10 and exposes at least a portion of the non-display area of the display panel 10. For example, a portion of the display panel 10 including the display electrode pads may not be covered with the protection substrate 30.

The protection substrate 30 may be formed of a material or at a thickness having sufficient rigidity to prevent the display apparatus 1 from being easily deformed by an external physical shock.

The protection substrate 30 may be made of a material having insulating properties to protect the display panel 10 from an external electrical shock and having light-transmitting properties to reduce a decrease in light emission efficiency of the display panel 10.

As an example, in an embodiment the protection substrate 30 may be made of a glass material including SiO₂ as a main component. Alternatively, the protection substrate 30 may be made of any one plastic material of polyethersulfone (PES), polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose triacetate (TAC), and cellulose acetate propionate (CAP).

The display driving circuit 40 supplies signals and power for driving the display panel 10.

The display driving circuit 40 may supply data signals to data lines of the display panel 10. In addition, the display driving circuit 40 may further supply first driving power to first driving power lines of the display panel 10. In addition, the display driving circuit 40 may supply a scan control signal to a scan driver embedded in the display panel 10.

The display driving circuit 40 may be provided as an integrated circuit (IC) chip.

In an embodiment, the integrated driving circuit of the display driving circuit 40 may be directly mounted on the display panel 10 in a chip on glass (COG) manner, a chip on plastic (COP) manner, or an ultrasonic bonding manner. In this embodiment, as illustrated in FIG. 2, the integrated circuit chip of the display driving circuit 40 may be disposed in an area that is not covered by the protection substrate 30 in the non-display area of the display panel 10.

Alternatively, the integrated circuit chip of the display driving circuit 40 may be mounted on the display circuit board 50.

The display circuit board 50 may include an anisotropic conductive film. As an example, the display circuit board 50 may be a flexible printed circuit board, a printed circuit board, or a flexible film such as a chip on film.

The display circuit board 50 may be attached to the display electrode pads of the display panel 10. Therefore, lead lines of the display circuit board 50 may be electrically connected to the display electrode pads of the display panel 10.

The touch driving circuit 60 may be provided as an integrated circuit (IC) chip.

The integrated circuit chip of the touch driving circuit 60 may be mounted on the touch circuit board 61. Since the touch circuit board 61 is electrically connected to the touch electrode pads of the touch sensing unit 20, the integrated circuit chip of the touch driving circuit 60 may be connected to touch electrodes of the touch sensing unit 20 through the touch circuit board 61 and the touch electrode pads.

The touch driving circuit 60 applies touch driving signals to the touch electrodes of the touch sensing unit 20 and measures capacitance values of the touch electrodes. The touch driving signal may be a signal having a plurality of driving pulses. The touch driving circuit 60 may determine whether or not a touch has been input according to the capacitance values, and calculate coordinates of a point where the touch is input.

In an embodiment, the touch circuit board 61 may include an anisotropic conductive film.

The lead lines of the touch circuit board 61 are attached to the touch electrode pads of the touch sensing unit 20, and may thus be electrically connected to the touch electrode pads of the touch sensing unit 20. In an embodiment, the touch circuit board 61 may be a flexible printed circuit board, a printed circuit board, or a flexible film such as a chip-on film.

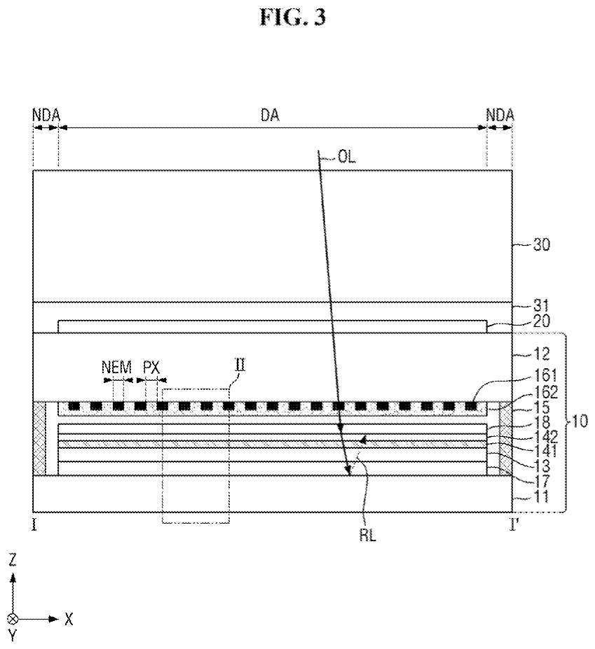

FIG. 3 is a cross-sectional view illustrating an example taken along I-I′ of FIG. 2.

The display apparatus 1 includes the display panel 10 emitting light for the display of an image.

Referring to FIG. 3, the display panel 10 includes a support substrate 11 including a display area DA in which a plurality of pixel areas PX for displaying an image are arranged and a non-display area NDA disposed around the display area, an encapsulation substrate 12 facing the support substrate 11, an emitting array 13 disposed on one side of the support substrate 11 facing the encapsulation substrate 12, a phase adjusting layer 141 disposed on the emitting array 13 and changing a phase of light, a reflected light absorbing layer 142 disposed on the phase adjusting layer 141 and absorbing at least a portion of light reflected from the emitting array 13, a sealing layer 15 disposed in the non-display area NDA between the support substrate 11 and the encapsulation substrate 12 and bonding the support substrate 11 and the encapsulation substrate 12 to each other, and a black matrix layer 161 disposed on one side of the encapsulation substrate 12 facing the support substrate 11 and corresponding to non-emission areas NEM that are boundaries between the plurality of pixel areas PX.

The display panel 10 may further include a reflection adjusting layer 162 disposed on one side of the encapsulation substrate 12, covering the black matrix layer 161, and absorbing at least a portion of light incident from the encapsulation substrate 12.

The display panel 10 may further include a circuit array 17 disposed on one side of the support substrate 11 and including a plurality of pixel driving circuits corresponding to the plurality of pixel areas PX. The emitting array 13 may be disposed on the circuit array 17.

The display panel 10 may further include a sealing structure 18 disposed on the reflected light absorbing layer 142 to further reduce penetration of moisture or oxygen into the emitting array 13.

In an embodiment, the support substrate 11 may be provided in the form of a rigid flat plate. Alternatively, the support substrate 11 may be provided in the form of a flexible flat plate that may be easily deformed, for example, bent, folded, or rolled.

The support substrate 11 may be made of an insulating material such as glass, quartz, or a polymer resin. In an embodiment, the polymer resin may include polyethersulphone (PES), polyacrylate (PA), polyarylate (PAR), polyetherimide (PEI), polyethylene naphthalate (PEN), polyethylene terepthalate (PET), polyphenylene sulfide (PPS), polyallylate, polyimide (PI), polycarbonate (PC), cellulose triacetate (TAC), cellulose acetate propionate (CAP), or combinations thereof. However, embodiments of the present disclosure are not necessarily limited thereto.

Alternatively, the support substrate 11 may be made of a metal material.

The support substrate 11 supports the circuit array 17, the emitting array 13, and the like, disposed between the support substrate 11 and the encapsulation substrate 12.

The encapsulation substrate 12 may be provided in the form of a rigid flat plate including at least the display area DA. The encapsulation substrate 12 may be made of a material having light-transmitting properties and insulating properties. As an example, the encapsulation substrate 12 may be made of any one of glass, quartz, and a polymer resin.

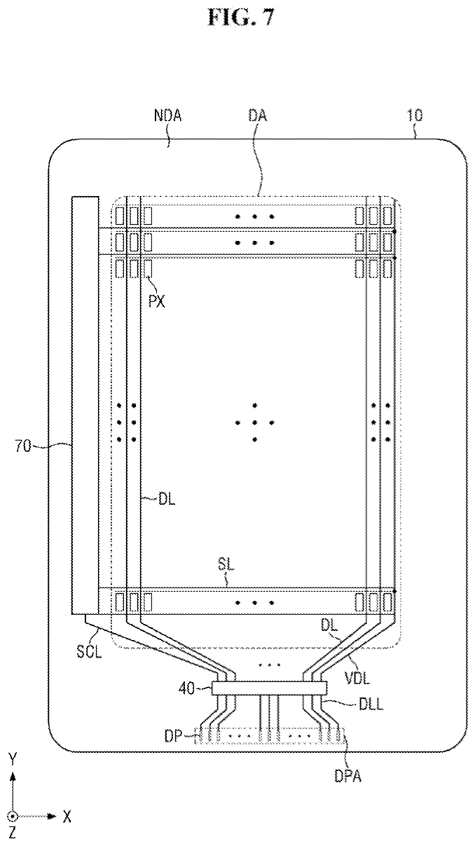

In an embodiment, the non-display area NDA of the encapsulation substrate 12 may have a smaller width than the support substrate 11 to expose display electrode pads DP (see FIG. 7), and the like, disposed in the non-display area NDA of the support substrate 11.

The encapsulation substrate 12 faces the support substrate 11 and is bonded to the support substrate 11, and seals the emitting array 13 and the like disposed between the support substrate 11 and the encapsulation substrate 12 together with the support substrate 11 and the sealing layer 15.

The encapsulation substrate 12 may be provided to be thicker than the support substrate 11 to provide rigidity for maintaining a shape of the display panel 10. As an example, in an embodiment the encapsulation substrate 12 may have a thickness of about 200 μm or more.

The sealing layer 15 may be disposed between the support substrate 11 and the encapsulation substrate 12, and may be formed in a frame-shaped pattern surrounding the display area DA.

The sealing layer 15 may be made of an organic material having adhesiveness. As an example, the sealing layer 15 may be made of an epoxy-based resin.

By such a sealing layer 15, the support substrate 11 and the encapsulation substrate 12 may be bonded to each other, and a space between the support substrate 11 and the encapsulation substrate 12 may be sealed.

The circuit array 17 is disposed on one side of the support substrate. 11, and includes the plurality of pixel driving circuits corresponding to the plurality of pixel areas PX. Each of the plurality of pixel driving circuits includes at least one transistor.

The emitting array 13 is disposed on the circuit array 17, and includes a plurality of emitting devices corresponding to the plurality of pixel areas PX. Each of the plurality of emitting devices includes a first electrode and a second electrode facing each other, and an emitting structure disposed between the first electrode and the second electrode.

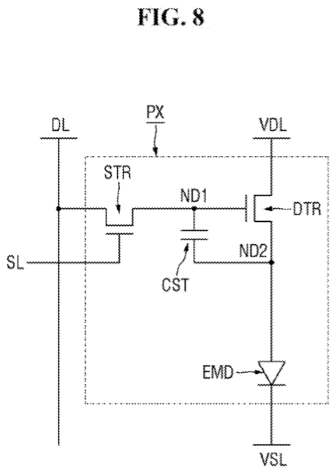

The circuit array 17 and the emitting array 13 will be described later with reference to FIGS. 7 and 8.

The phase adjusting layer 141 is disposed on the emitting array 13, and changes a phase of light.

For example, the phase of the light passing through the phase adjusting layer 141 is delayed by a phase difference corresponding to a thickness of the phase adjusting layer 141.

As an example, in an embodiment the phase adjusting layer 141 may delay the phase of the light by λ/4. In this embodiment, the light passing through the phase adjusting layer 141 twice has a phase delayed by λ/2. For example, the phase of the light passing through the phase adjusting layer 141 twice is opposite to a phase of light that does not pass through the phase adjusting layer 141. Therefore, a phase difference between the light passing through the phase adjusting layer 141 twice and the light that does not pass through the phase adjusting layer 141 is 180°.

In this embodiment, a phase of light OL (hereinafter referred to as “outside light”) incident from the outside of the display panel 10 toward the emitting array 13 through the encapsulation substrate 12 having the light-transmitting properties is delayed by λ/4 by the phase adjusting layer 141. In addition, a portion of the outside light OL having the phase delayed by λ/4 by the phase adjusting layer 141 is reflected by the emitting array 13. In addition, a portion of the outside light reflected from the emitting array 13 becomes reflected light RL passing through the phase adjusting layer 141 and directed to the encapsulation substrate 12.

Since a phase of the reflected light RL is delayed by λ/4 by the phase adjusting layer 141, the reflected light RL has a phase delayed by λ/2 as compared with the outside light OL. For example, a phase difference between the reflected light RL and the outside light OL is 180°. Therefore, the reflected light RL has the same magnitude as and an opposite phase to the outside light OL.

Accordingly, destructive interference between the reflected light RL and the outside light OL may be induced in the reflected light absorbing layer 142 disposed on the phase adjusting layer 141. Based on this, the reflected light absorbing layer 142 may absorb at least a portion of the reflected light RL.

In an embodiment, the reflected light absorbing layer 142 may be made of a material having a refractive index of about 1 or more and an absorption coefficient of about 0.5 or more. In addition, the reflected light absorbing layer 142 may be made of an inorganic material that may be thermally deposited for an easy disposition process. For example, the reflected light absorbing layer 142 may be made of an inorganic material having a refractive index of about 1 or more and an absorption coefficient of about 0.5 or more.

As an example, the reflected light absorbing layer 142 may be made of at least one of bismuth (Bi) and ytterbium (Yb).

The sealing structure 18 may be provided in a structure in which a plurality of sealing layers made of different materials or having different thicknesses are stacked.

The black matrix layer 161 are disposed on one side of the encapsulation substrate 12 facing the support substrate 11, and correspond to the non-emission areas NEM that are the boundaries between the plurality of pixel areas PX in the display area DA. The black matrix layer 161 may be made of a light blocking material or a light absorbing material.

Light emission in the non-emission areas NEM that are the boundaries between the plurality of pixel areas PX, in the display area DA may be blocked by such black matrix layer 161.

In addition, the black matrix layer 161 become slits for allowing the light of the emitting array 13 to be emitted only through the pixel areas PX. Accordingly, when a gap between the black matrix layer 161 and the emitting array 13 becomes greater than a threshold, a parallax may occur due to the gap between the black matrix layer 161 and the emitting array 13.

However, according to an embodiment, the black matrix layer 161 are disposed on one side of the encapsulation substrate 12 facing the support substrate 11, and thus, the gap between the black matrix layer 161 and the emitting array 13 is not affected by the thickness of the encapsulation substrate 12. Therefore, a parallax due to the gap between the black matrix layer 161 and the emitting array 13 may be prevented regardless of the encapsulation substrate 12 having a relatively thick thickness.

The reflection adjusting layer 162 is disposed on one side of the encapsulation substrate 12. The reflection adjusting layer 162 may cover the black matrix layer 161.

The reflection adjusting layer 162 absorbs another portion of the outside light OL. For example, the reflection adjusting layer 162 may absorb light of a wavelength region that is not emitted from the plurality of pixel areas PX included in the display area DA among the outside light OL of a visible ray band.

To this end, the reflection adjusting layer 162 may be made of an organic material including a dye or a pigment absorbing light of a specific wavelength region.

As an example, when each of the plurality of pixel areas PX corresponds to any one of red, green, and blue, a minimum absorption wavelength region of the dye or the pigment included in the organic material constituting the reflection adjusting layer 162 may be a wavelength region that does not correspond to any of the red, the green, and the blue. For example, the minimum absorption wavelength region of the dye or the pigment included in the organic material constituting the reflection adjusting layer 162 may be a wavelength region in a range of about 490 nm to about 505 nm or a wavelength region in a range of about 585 nm to about 600 nm.

Accordingly, a ratio in which light of a wavelength region absorbed by the dye or the pigment of the reflection adjusting layer 162 among the outside light OL is emitted to the encapsulation substrate 12 is decreased, and thus, outside light reflection may be reduced. In addition, light of a wavelength region corresponding to any one of the red, the green, and the blue among the outside light OL passes through the reflection adjusting layer 162 together with the light emitted from the emitting array 13, such that light efficiency and luminance for each color of the display panel 10 may be increased.

As described above, the display panel 10 according to an embodiment includes the phase adjusting layer 141 and the reflected light absorbing layer 142 disposed on the emitting array 13, such that the destructive interference between the reflected light RL by the emitting array 13 and the outside light OL may be induced, and thus, a ratio in which the reflected light RL is emitted toward the encapsulation substrate 12 may be reduced.

In addition, the display panel 10 according to an embodiment includes the reflection adjusting layer 162 disposed on one side of the encapsulation substrate 12, and it is thus possible to increase a ratio in which light of a wavelength region similar to that of the light emitted from the plurality of pixel areas PX among the outside light OL is emitted while decreasing a ratio in which light of a wavelength region different from that of the light emitted from the plurality of pixel areas PX among the outside light OL is emitted toward the encapsulation substrate 12. Accordingly, it is possible to increase light emission efficiency of the display panel 10 while reducing the outside light reflection.

In addition, the display panel 10 according to an embodiment includes the black matrix layer 161 disposed on one side of the encapsulation substrate 12, and thus, the light emission in the non-emission areas NEM may be blocked. For example, the black matrix layer 161 is disposed on one side of the encapsulation substrate 12 facing the support substrate 11, and thus, the occurrence of the parallax due to addition of a thickness of the encapsulation substrate 12 to the gap between the emitting array 13 and the black matrix layer 161 may be prevented.

Therefore, the display panel 10 according to an embodiment includes the phase adjusting layer 141, the reflected light absorbing layer 142, the black matrix layer 161, and the reflection adjusting layer 162, and thus, a phenomenon in which visibility of the emitting array 13 is increased by the reflected light RL, that is, the outside light reflection may be reduced, without including a polarizing plate. Accordingly, a decrease in light efficiency due to the polarizing plate may be prevented, and thus, light emission efficiency and display quality of the display panel 10 may be increased.

In addition, as illustrated in FIG. 3, the display apparatus 1 may further include a touch sensing unit 20 disposed on the display panel 10.

In an embodiment, the touch sensing unit 20 may be disposed on the other side of the encapsulation substrate 12 (e.g., an upper side in the Z-axis direction). Alternatively, the touch sensing unit 20 may be disposed on one side of the encapsulation substrate 12 to be embedded in the display panel 10.

In addition, the display apparatus 1 may further include a protection substrate 30 attached onto the display panel 10 through an adhesive layer 31 covering the touch sensing unit 20.

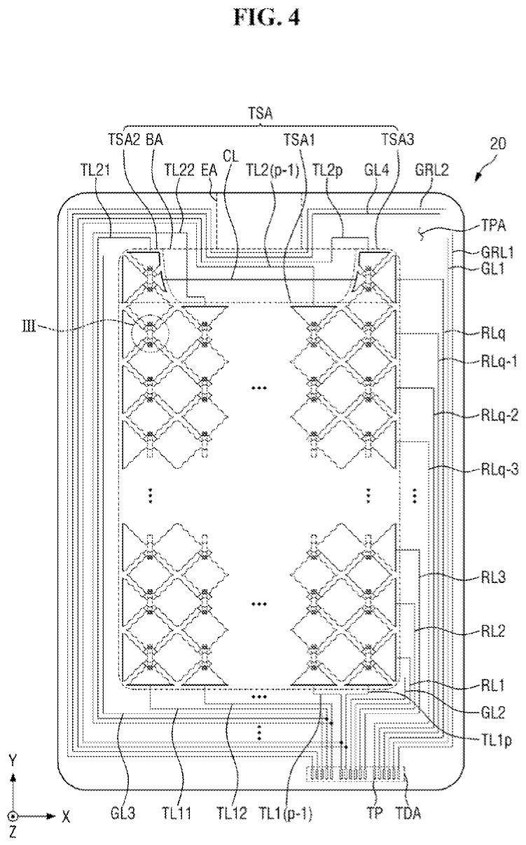

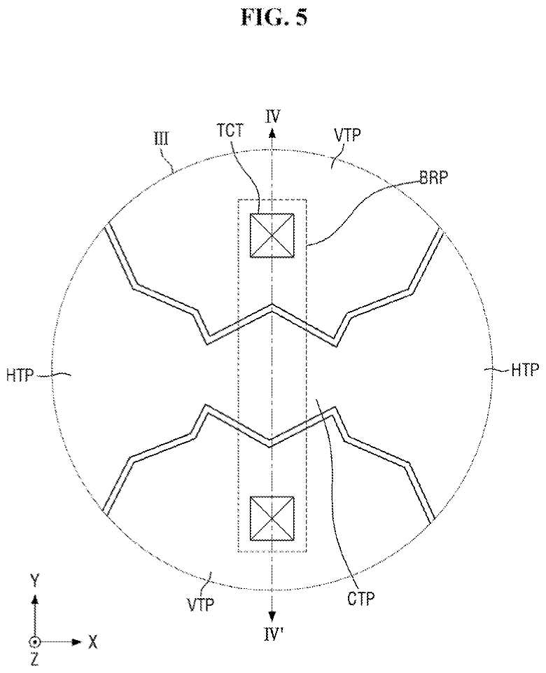

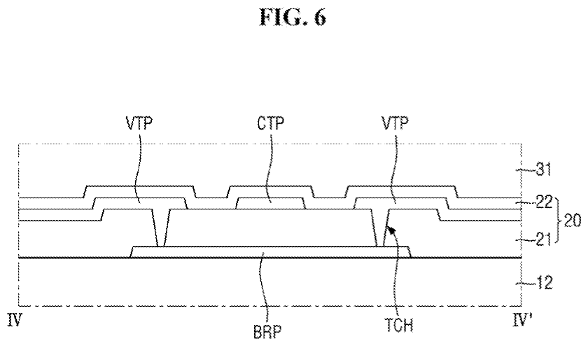

FIG. 4 is a plan view illustrating an example of a touch sensing unit of FIG. 3. FIG. 5 is an enlarged view illustrating portion III of FIG. 4. FIG. 6 is a cross-sectional view taken along line IV-IV′ of FIG. 5.

Referring to FIG. 4, the touch sensing unit 20 includes a touch sensor area TSA for detecting a touch point and a touch peripheral area TPA, which is a peripheral area of the touch sensor area. The touch sensor area TSA may correspond to the display area DA of the display panel 10, and the touch peripheral area TPA may correspond to the non-display area NDA of the display panel 10. As an example, the touch sensor area TSA may overlap the display area DA, and the touch peripheral area TPA may overlap at least a portion of the non-display area NDA.

In an embodiment, the touch sensor area TSA may include a first touch sensor area TSA1 having a rectangular shape, a second touch sensor area TSA2 protruding from one corner of the first touch sensor area TSA1 (e.g., an upper left corner), a third touch sensor area TSA3 protruding from the other corner of the first touch sensor area TSA1 (e.g., an upper right corner), and a bay area BA disposed between the second touch sensor area TSA2 and the third touch sensor area TSA3 (e.g., in the X-axis direction).

The touch sensing unit 20 includes first touch lines TL11, TL12, TL1(p−1), and TL1p (here, p is a natural number of 4 or more) disposed in the first touch sensor area TSA1 and extending in the first direction (Y-axis direction) and second touch lines RL1, RL2, RL3, RLq−3, RLq−2, and RLq (here, q is a natural number of 7 or more) disposed in the touch sensor area TSA and extending in the second direction (X-axis direction).

The touch sensing unit 20 may further include third touch lines TL21, TL22, TL2(p−1), and TL2p disposed in the second touch sensor area TSA2 and the third touch sensor area TSA3 and extending in the first direction (Y-axis direction).

The touch sensing unit 20 may further include a first guard line GL1, a second guard line GL2, a third guard line GL3, a fourth guard line GL4, a first ground line GRL1, and a second ground line GRL2 disposed in the touch peripheral area TPA.

The first guard line GL1 may be disposed outside any one second touch line RLq farthest away from the touch sensor area TSA among the second touch lines RL1, RL2, RL3, RLq−3, RLq−2, and RLq so as to be in parallel with any one second touch line RLq. Here, the term “outside” refers to a direction toward an edge parallel and adjacent to the second touch lines RL1, RL2, RL3, RLq−3, RLq−2, and RLq among edges of a shape of the touch sensing unit 20 in a plan view.

The first ground line GRL1 may be disposed outside the first guard line GL1 so as to be parallel to the first guard line GL1.

An electrical influence of the first ground line GRL1 on the second touch lines RL1, RL2, RL3, RLq−3, RLq−2, and RLq may be decreased by the first guard line GL1.

The second guard line GL2 is disposed between the second touch lines RL1, RL2, RL3, RLq−3, RLq−2, and RLq and the first touch lines TL11, TL12, TL1(p−1), and TL1p.

An electrical influence between the second touch lines RL1, RL2, RL3, RLq−3, RLq−2, and RLq and the first touch lines TL11, TL12, TL1(p−1), and TL1p may be decreased by the second guard line GL2.

The third guard line GL3 may be disposed between the first touch lines TL11, TL12, TL1(p−1), and TL1p and the third touch lines TL21, TL22, TL2(p−1), and TL2p.

An electrical influence between the first touch lines TL11, TL12, TL1(p−1), and TL1p and the third touch lines TL21, TL22, TL2(p−1), and TL2p may be decreased by the third guard line GL3.

The fourth guard line GL4 may be disposed between the second touch lines RL1, RL2, RL3, RLq−3, RLq−2, and RLq and the third touch lines TL21, TL22, TL2(p−1), and TL2p.

An electrical influence between the second touch lines RL1, RL2, RL3, RLq−3, RLq−2, and RLq and the third touch lines TL21, TL22, TL2(p−1), and TL2p may be decreased by such a fourth guard line GL4.

Each of the first touch lines TL11, TL12, TL1(p−1), and TL1p may include first electrode patterns (e.g., vertical touch electrode patterns VTP (see FIG. 5) arranged in parallel in the first direction (Y-axis direction).

Each of the second touch lines RL1, RL2, RL3, RLq−3, RLq−2, and RLq may include second electrode patterns (e.g., horizontal touch electrode patterns HTP (see FIG. 5) arranged in parallel in the second direction (X-axis direction).

The third touch lines TL21, TL22, TL2(p−1), and TL2p are connected to the first electrode patterns VTP disposed in the second touch sensor area TSA2 and the third touch sensor area TSA3.

In addition, the touch sensing unit 20 may further include a connection line CL extending in the second direction (X-axis direction) in the bay area BA. The connection line CL connects between the second electrode pattern of the second touch sensor area TSA2 and the second electrode pattern of the third touch sensor area TSA3.

The touch sensing unit 20 may further include touch electrode pads TP disposed in a touch pad area TDA adjacent to an edge of the touch sensing unit 20 in the touch peripheral area TPA.

In addition, the touch sensing unit 20 may further include an empty area EA formed of a portion adjacent to one side of the bay area BA of the touch peripheral area TPA.

The empty area EA is an area in which a sensor device such as a camera embedded in the display apparatus 1 is to be disposed. For example, when the display apparatus 1 is implemented as a multi-functional smart device such as a mobile phone, a smartphone, and a tablet personal computer (PC), the display apparatus 1 may have a sensor device such as a camera device, a proximity sensor device, an illuminance sensor device, and an iris recognition sensor device, embedded therein. In this embodiment, when the sensor device is disposed in the empty area EA, an increase in a bezel width due to the embedding of the sensor device may be prevented.

Referring to FIG. 6, a bridge pattern BRP formed in a line shape in the first direction is overlapped between the first touch electrode patterns VTP neighboring to each other (e.g., adjacent to each other) in the first direction (Y-axis direction).

For example, each of the first touch lines TL11, TL12, TL1(p−1), and TL1p includes the first electrode patterns VTP (see FIG. 5) arranged in parallel in the first direction (Y-axis direction) and the bridge pattern BRP connecting between the first electrode patterns VTP neighboring to each other (e.g., adjacent to each other) in the first direction (Y-axis direction).

A contact pattern CTP formed in a line shape in the second direction (X-axis direction) is disposed between the second electrode patterns HTP neighboring to each other (e.g., adjacent to each other) in the second direction (X-axis direction).

For example, each of the second touch lines RL1, RL2, RL3, RLq−3, RLq−2, and RLq includes the second electrode patterns HTP (see FIG. 5) arranged in parallel in the second direction (X-axis direction) and the contact pattern CTP connecting between the second electrode patterns HTP neighboring to each other (e.g., adjacent to each other) in the second direction (X-axis direction).

The bridge pattern BRP is disposed at a different layer from the first electrode pattern VTP, the second electrode pattern HTP, and the contact pattern CTP, and crosses the contact pattern CTP.

Accordingly, the first electrode pattern VTP may be connected to the bridge pattern BRP through a touch contact hole TCH.

For example, referring to FIG. 6, the bridge pattern BRP may be disposed on the other side of the encapsulation substrate 12, and the first electrode pattern VTP, the second electrode pattern HTP, and the contact pattern CTP may be disposed on an inter-touch layer insulating layer 21 covering the bridge pattern BRP.

In this embodiment, the first electrode pattern VTP may be connected to the bridge pattern BRP through the touch contact hole TCH penetrating the inter-touch layer insulating layer 21.

In addition, the touch sensing unit 20 may further include a touch protection layer 22 covering the first electrode pattern VTP, the second electrode pattern HTP, and the contact pattern CTP.

However, a cross section of the touch sensing unit 20 illustrated in FIG. 6 is only an example, and a structure of the touch sensing unit 20 may be modified into any structure as long as the bridge pattern BRP may be disposed at a different layer from the first electrode pattern VTP, the second electrode pattern HTP, and the contact pattern CTP.

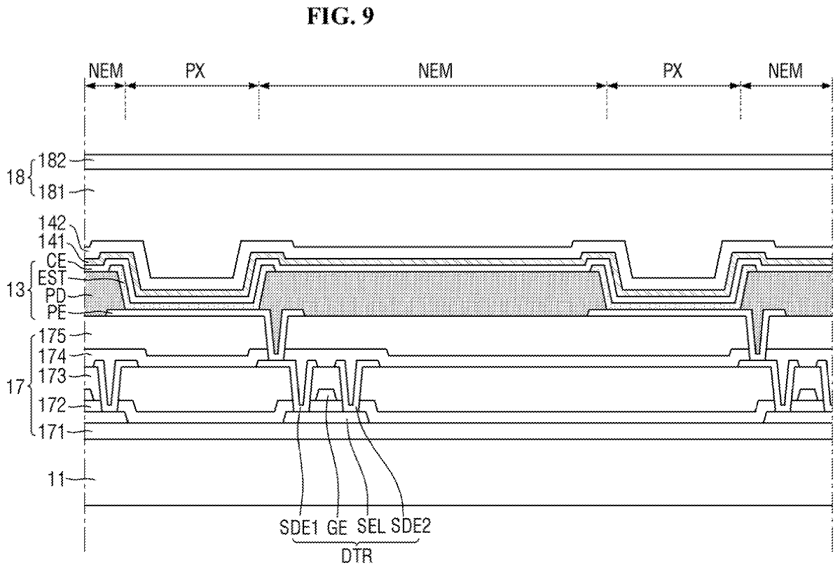

FIG. 7 is a plan view illustrating an example of a display panel of FIG. 3. FIG. 8 is an equivalent circuit diagram illustrating an example of a pixel driving circuit corresponding to any one pixel area of FIG. 7. FIG. 9 is a cross-sectional view illustrating an example of a driving transistor and an emitting device of FIG. 8.

Referring to FIG. 7, the display panel 10 includes a display area DA emitting light for displaying an image, and a non-display area NDA, which is a peripheral area of the display area DA. The non-display area NDA may be an area from an edge of the display area DA to an edge of the support substrate 11 (see FIG. 3).

The display panel 10 includes a plurality of pixel areas PX arranged in a matrix form in parallel in the first direction (Y-axis direction) and the second direction (X-axis direction) in the display area DA. Each of the plurality of pixel areas PX may be a unit area individually displaying luminance.

The display panel 10 may further include display electrode pads DP disposed in a display electrode pad area DPA disposed adjacent to the edge of the support substrate 11 in the non-display area NDA. For example, in an embodiment the display electrode pad area DPA may be disposed on a lower edge of the support substrate 11 (e.g., in the Y-axis direction). However, embodiments of the present disclosure are not necessarily limited thereto.

The display circuit board 50 (see FIGS. 1 and 2) may be disposed on the display electrode pad area DPA and be electrically connected to the display electrode pads DP.

The display panel 10 further includes wirings disposed in the display area DA and supplying signals or power to the plurality of pixel areas PX. As an example, the display panel 10 may include wirings such as scan lines SL, data lines DL, and first driving power lines VDL.

The data lines DL may be disposed to extend in the first direction (Y-axis direction).

The scan lines SL may be disposed to extend in the second direction (X-axis direction).

The first driving power lines VDL may be disposed to extend in at least one of the first direction (Y-axis direction) and the second direction (X-axis direction). As an example, the first driving power lines VDL may be disposed to extend in the first direction (Y-axis direction) like the data lines DL.

The scan lines SL supply scan signals for selecting pixel areas arranged in parallel in the second direction (X-axis direction) as pixel areas to which data signals are to be written.

The scan lines SL may be connected to a scan driver 70 disposed in a portion of the non-display area NDA of the display panel 10.

The scan driver 70 may receive a scan control signal from the display driving circuit 40 through at least one scan control line SCL.

The scan driver 70 may sequentially supply scan signals to a plurality of scan lines SL arranged in the display area DA during each frame period for displaying an image, based on the scan control signal of the scan control line SCL.

Referring to FIG. 7, the scan driver 70 is disposed in a portion of the non-display area NDA adjacent to one side (left side of FIG. 7) of the display area DA in the second direction (X-axis direction). However, this is only an example, and the scan driver 70 may be disposed in another portion of the non-display area NDA adjacent to the other side (right side of FIG. 7) of the display area DA, etc. Alternatively, the scan driver 70 may be disposed on both sides of the display area DA in the left and right direction.

The data lines DL are connected to pixel areas arranged in parallel to extend in the first direction (Y-axis direction), and supply data signals corresponding to luminance of the pixel areas to which the scan signals of the scan lines SL are supplied.

The data lines DL may be connected to the display driving circuit 40, and the display driving circuit 40 may supply data signals of the pixel areas to which the scan signals of the scan lines SL are supplied, to the data lines DL.

The display driving circuit 40 may be connected to the display electrode pads DP through data link lines DLL, and may receive digital video data and timing signals from the display circuit board 50 connected to the display electrode pads DP.

The first driving power lines VDL supply first driving power for driving emitting devices EMD (see FIG. 8).

The first driving power lines VDL may receive the first driving power from the display driving circuit 40 or the display circuit board 50.

Each of the plurality of pixel areas PX includes a pixel driving circuit supplying a driving current to the emitting device EMD based on signals and power supplied through wirings such as the scan line SL, the data line DL, the first driving power line VDL, and the like.

Referring to FIG. 8, each of the plurality of pixel areas PX may include a pixel driving circuit including an emitting device EMD, a driving transistor DTR, a switching transistor STR, and a storage capacitor CST.

The emitting device EMD may be an organic light emitting diode including a first electrode and a second electrode facing each other and an emitting layer made of an organic emitting material between the first electrode and the second electrode. Alternatively, the emitting device EMD may include an emitting layer made of an inorganic photoelectric conversion material.

The driving transistor DTR is connected to the emitting device EMD in series between a first driving power line VDL and a second driving power line VSL. The second driving power line VSL may supply second driving power having a lower voltage level than first driving power of the first driving power line.

As an example, an anode electrode of the emitting device EMD may be connected to a drain electrode of the driving transistor DTR, and a cathode electrode of the emitting device EMD may be connected to the second driving power line VSL.

In addition, a gate electrode of the driving transistor DTR may be connected to the first node ND1 corresponding to the switching transistor STR, any one of a source electrode and the drain electrode of the driving transistor DTR may be connected to a second node ND2 corresponding to the emitting device EMD, and the other of the source electrode and the drain electrode of the driving transistor DTR may be connected to the first driving power line VDL.

The storage capacitor CST is disposed between a first node ND1 and a second node ND2. The first node ND1 is a contact point between the gate electrode of the driving transistor DTR and the switching transistor STR. The second node ND2 is a contact point between the driving transistor DTR and the emitting device EMD.

The switching transistor STR is disposed between a data line DL and the first node ND1, and is turned on based on a scan signal of a scan line SL. For example, a gate electrode of the switching transistor STR may be connected to the scan line SL any one of a source electrode and a drain electrode of the switching transistor STR may be connected to the data line DL, and the other of the source electrode and the drain electrode of the switching transistor STR may be connected to the first node ND1.

Accordingly, when the scan signal is supplied to the scan line SL, the switching transistor STR is turned on based on the scan signal of the scan line SL, and a data signal of the data line DL is transferred to the first node ND1 through the turned-on switching transistor STR.

The driving transistor DTR generates a driving current having a magnitude corresponding to a voltage difference between the first node ND1 and the first driving power line VDL. In this embodiment, the emitting device EMD emits light having luminance corresponding to the driving current of the driving transistor DTR.

FIG. 8 illustrates a pixel driving circuit having a 2T1C structure, but this is only an example. For example, the pixel driving circuit of the display panel 10 according to an embodiment is not necessarily limited to that illustrated in FIG. 8, and may be variously modified.

FIG. 8 illustrates that the driving transistor DTR and the switching transistor STR are formed as metal oxide semiconductor field effect transistors (MOSFETs), but this is only an example. For example, at least one transistor included in the pixel driving circuit of the display panel 10 according to an embodiment may be a P-type MOSFET.

Referring to FIG. 9, the display panel 10 may include a circuit array 17 disposed on the support substrate 11 and including a pixel driving circuit corresponding to each of the plurality of pixel areas PX, a emitting array 13 disposed on the circuit array 17 and including an emitting device EMD corresponding to each of the plurality of pixel areas PX, a phase adjusting layer 141 disposed on the emitting array 13, a reflected light absorbing layer 142 disposed on the phase adjusting layer 141, and a sealing structure 18 disposed on the reflected light absorbing layer 142.

For example, the driving transistor DTR included in each of the pixel driving circuits of the circuit array 17 may include a semiconductor layer SEL disposed on a buffer layer 171 covering one side of the support substrate 11, a gate electrode GE disposed on a gate insulating layer 172 covering the semiconductor layer SEL and overlapping a channel region of the semiconductor layer SEL, a source electrode SDE1 disposed on an interlayer insulating layer 173 covering the gate electrode GE and connected to a source region of the semiconductor layer SEL in contact with one side of the channel region, and a drain electrode SDE2 disposed on the interlayer insulating layer 173, spaced apart from the source electrode SDE1, and connected to a drain region of the semiconductor layer SEL in contact with the other side of the channel region.

In addition, in an embodiment the driving transistor DTR may further include a light blocking layer disposed on the support substrate 11, covered with the buffer layer 171, and overlapping the channel region of the semiconductor layer SEL. Due to the light blocking layer, it is possible to prevent outside light passing through the support substrate 11 from reaching the semiconductor layer SEL, and thus, it is possible to prevent a change in characteristics of the semiconductor layer SEL due to the outside light.

The buffer layer 171 may be entirely disposed on one side of the support substrate 11. In an embodiment, the buffer layer 171 may be formed as a single layer or multiple layers made of at least one of silicon nitride, silicon oxide, and silicon oxynitride.

The semiconductor layer SEL may be made of an oxide semiconductor. In an embodiment, the oxide semiconductor may include at least one of a binary compound (ABₓ), a ternary compound (ABₓC_{y}), and a quaternary compound (ABₓC_{y}D_{z}) containing indium (In), zinc (Zn), gallium (Ga), tin (Sn), titanium (Ti), aluminum (Al), hafnium (Hf), zirconium (Zr), magnesium (Mg), and the like.

In an embodiment in which the semiconductor layer SEL is made of the oxide semiconductor, at least a portion of each of the source region and the drain region of the semiconductor layer SEL may be made into a conductor.

In an embodiment, the gate insulating layer 172 may be entirely disposed on the buffer layer 171. Alternatively, the gate insulating layer 172 may be partially disposed only below the gate electrode GE.

In an embodiment, the gate insulating layer 172 may include a silicon compound, a metal oxide, or the like. For example, the gate insulating layer 172 may include silicon oxide, silicon nitride, silicon oxynitride, aluminum oxide, tantalum oxide, hafnium oxide, zirconium oxide, titanium oxide, or the like.

In an embodiment, the gate electrode GE may be formed as a single layer or multiple layers made of at least one of silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca), and mixtures thereof.

As an example, the gate electrode GE may be a double layer including a lower layer disposed on the gate insulating layer 172 and an upper layer disposed on the lower layer and made of a low-resistance material. Here, the lower layer may be to prevent diffusion of a material constituting the upper layer into the semiconductor layer SEL, and may be made of titanium (Ti). In addition, the upper layer may be made of copper (Cu) having a relatively low resistance.

The interlayer insulating layer 173 may be entirely disposed on the gate insulating layer 172.

In an embodiment, the interlayer insulating layer 173 may be made of an inorganic insulating material such as silicon oxide, silicon nitride, silicon oxynitride, hafnium oxide, aluminum oxide, titanium oxide, tantalum oxide, and zinc oxide.

The source electrode SDE1 may be disposed on the interlayer insulating layer 173, and may be connected to the source region of the semiconductor layer SEL through a hole penetrating through at least the interlayer insulating layer 173.

The drain electrode SDE2 may also be disposed on the interlayer insulating layer 173, and may be connected to the drain region of the semiconductor layer SEL through a hole penetrating through at least the interlayer insulating layer 173.

In an embodiment, the source electrode SDE1 and the drain electrode SDE2 may be made of at least one of silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca), and mixtures thereof.

The circuit array 17 may further include an auxiliary interlayer insulating layer 174 covering the source electrode SDE1 and the drain electrode SDE2 and a via layer 175 disposed on the auxiliary interlayer insulating layer 174.

In an embodiment, the auxiliary interlayer insulating layer 174 may be entirely disposed on the interlayer insulating layer 173. In an embodiment, the auxiliary interlayer insulating layer 174 may prevent separation between the source electrode SDE1 and the drain electrode SDE2, and the via layer 175, and may be made of an inorganic insulating material such as silicon oxide, silicon nitride, silicon oxynitride, hafnium oxide, aluminum oxide, titanium oxide, tantalum oxide, and zinc oxide, similar to the interlayer insulating layer 173.

In an embodiment, the via layer 175 may be entirely disposed on the auxiliary interlayer insulating layer 174.

The via layer 175 may be formed to have a thickness sufficient to remove the step difference of the circuit array 17 and remove unnecessary electrical interference between the circuit array 17 and the emitting array 13.

In an embodiment, the via layer 175 may include an organic insulating material such as a polyacrylates resin, an epoxy resin, a phenolic resin, a polyamides resin, a polyimides resin, an unsaturated polyesters resin, a polyphenyleneethers resin, a polyphenylenesulfides resin, or benzocyclobutene (BCB).

The via layer 175 may further include a photosensitive material.

The emitting array 13 may be disposed on the via layer 175.

In an embodiment, the emitting array 13 may include a plurality of first electrodes (pixel electrodes) PE corresponding to the plurality of pixel areas PX, a pixel defining layer PD corresponding to non-emission areas NEM and covering edges of each of the plurality of first electrodes PE, a plurality of emitting structures EST disposed on the plurality of first electrodes PE, respectively, and a second electrode (common electrode) CE disposed on the pixel defining layer PD and the plurality of emitting structures EST.

In this embodiment, each of a plurality of emitting devices EMD corresponding to the plurality of pixel areas PX has a structure in which each of the plurality of emitting structures EST is interposed between each of the plurality of first electrodes PE and the second electrode CE. For example, the emitting device EMD may be provided in a structure in which the emitting structure EST is interposed between the first electrode PE and the second electrode CE.

In an embodiment, the first electrode PE is provided as a pixel electrode corresponding to each of the plurality of pixel areas PX. The first electrode PE may be an anode electrode of the emitting device EMD.

The first electrode PE may include a first conductive layer made of a reflective material.

In addition, in consideration of the electrical characteristics between the first electrode PE and the emitting structure EST, the first electrode PE may further include a second conductive layer disposed below the emitting structure EST and made of a material having a high work function.

In an embodiment, the first conductive layer may be made of at least one reflective material of silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca), and mixtures thereof.

In addition, in an embodiment, the material having the high work function, corresponding to the second conductive layer may include at least one of indium tin oxide (ITO), indium zinc oxide (IZO), zinc oxide (ZnO), and indium oxide (In₂O₃).

For example, the first electrode PE may have a multilayer structure of ITO/Mg, ITO/MgF, ITO/Ag, and ITO/Ag/ITO.

The pixel defining layer PD may be provided as an insulating layer disposed entirely on the via layer 175 and including a hole corresponding to a central portion of each of the plurality of first electrodes PE.

In an embodiment, the pixel defining layer PD may be made of at least one organic insulating material of a polyacrylates resin, an epoxy resin, a phenolic resin, a polyamides resin, a polyimides resin, an unsaturated polyesters resin, a polyphenyleneethers resin, a polyphenylenesulfides resin, and benzocyclobutene (BCB).

Alternatively, the pixel defining layer PD may be made of an inorganic insulating material such as silicon oxide, silicon nitride, silicon oxynitride, hafnium oxide, aluminum oxide, titanium oxide, tantalum oxide, and zinc oxide.

The pixel defining layer PD may further include a light absorbing material. In this embodiment, light reflection by the pixel defining layer PD is prevented, such that light emission in the non-emission areas NEM may be reduced.

The emitting structure EST is disposed on each of the plurality of first electrodes PE. The emitting structure EST may be further disposed on the pixel defining layer PD at the edge and the periphery of the first electrode PE.

The emitting structure EST may be made of an organic material. In this embodiment, the emitting structure EST may include an emitting layer made of an organic emitting material, and a hole transport layer and an electron transport layer disposed on both sides of the emitting layer, respectively.

In an embodiment in which the display panel 10 displays a color image, each of the plurality of pixel areas PX may correspond to any one of two or more different colors. As example, each of the plurality of pixel areas PX may correspond to any one of red, green, and blue. However, embodiments of the present disclosure are not necessarily limited thereto.

In an embodiment, each of the emitting layers of the plurality of emitting structures EST corresponding to the plurality of pixel areas PX may include a dopant material or a host material corresponding to any one of two or more different colors.

As an example, when each of the plurality of pixel areas PX corresponds to any one of red, green, and blue, the emitting structure of the pixel area corresponding to the red may include an emitting layer including a dopant material corresponding to the red, the emitting structure of the pixel area corresponding to the green may include an emitting layer including a dopant material corresponding to the green, and the emitting structure of the pixel area corresponding to the blue may include an emitting layer including a dopant material corresponding to the blue.

The hole transport layer may be disposed between the emitting layer and the first electrode, and may include a hole transporting host material.

The electron transport layer may be disposed between the emitting layer and the second electrode, and may include an electron transporting host material.

The emitting structure EST may further include a hole injection layer disposed between the hole transport layer and the first electrode or an electron injection layer disposed between the electron transport layer and the second electrode.

Alternatively, the emitting structure EST may have a structure in which a plurality of stacks including respective emitting layers are stacked. In this embodiment, the emitting structure EST may further include a charge generating layer disposed between the plurality of stacks.

Alternatively, in an embodiment the emitting structure EST may be made of an inorganic semiconductor.

In an embodiment, the second electrode CE is provided as a common electrode commonly corresponding to the plurality of pixel areas PX. The second electrode CE may be a cathode electrode of the emitting device EMD.

The second electrode CE may include a third conductive layer made of a material having a low work function.

In an embodiment, the material having the low work function, corresponding to the third conductive layer may include Li, Ca, LiF/Ca, LiF/Al, Al, Mg, Ag, Pt, Pd, Ni, Au, Nd, Ir, Cr, BaF, Ba, or compounds or mixtures thereof (e.g., a mixture of Ag and Mg, etc.).

The second electrode CE may further include a fourth conductive layer disposed on the third conductive layer and made of a transparent conductive oxide.

The phase adjusting layer 141 may be disposed on the second electrode CE. The phase adjusting layer 141 changes a phase of the outside light OL entering the emitting array 13, and changes a phase of the outside light OL reflected by the emitting array 13.

In this embodiment, a phase difference by the phase adjusting layer 141 may correspond to a thickness of the phase adjusting layer 141.

As an example, the phase adjusting layer 141 may delay the phase of the light by λ/4. In this embodiment, the light that has reached the emitting array 13 through the phase adjusting layer 141, has been reflected from the emitting array 13, and has passed through the phase adjusting layer 141 again, that is, the light that has passed through the phase adjusting layer 141 twice may exhibit a phase difference of λ/2 as compared with the light that does not pass through the phase adjusting layer 141.

For example, the reflected light RL may have a phase opposite to that of the outside light OL by the phase adjusting layer 141, and thus, destructive interference between the reflected light RL and the outside light OL may be induced.

The reflected light absorbing layer 142 is disposed on the phase adjusting layer 141. The reflected light absorbing layer 142 may absorb at least a portion of the reflected light RL based on the destructive interference between the outside light OL that does not pass through the phase adjusting layer 141 and the reflected light RL that has passed through the phase adjusting layer 141 twice.

In addition, a portion of the outside light OL incident on the reflected light absorbing layer 142 may be absorbed by destructive interference with the reflected light RL, and another portion of the outside light OL incident on the reflected light absorbing layer may be reflected toward the encapsulation substrate 12.

In an embodiment, the reflected light absorbing layer 142 may be made of an inorganic material that has a refractive index of about 1 or more and an absorption coefficient of about 0.5 or more and may be thermally deposited. As an example, the reflected light absorbing layer 142 may be made of at least one of bismuth (Bi) and ytterbium (Yb).

The sealing structure 18 may be provided to prevent the emitting layer included in the emitting array 13 from being easily and quickly deteriorated by oxygen or moisture.

The sealing structure 18 may have a structure in which a plurality of sealing layer made of different materials or having different thicknesses are stacked.

As an example, in an embodiment the sealing structure 18 may include a first sealing layer 181 disposed on the reflected light absorbing layer 142 and made of an organic insulating material and a second sealing layer 182 disposed on the first sealing layer 181 and made of an inorganic insulating material.

For example, in an embodiment the first sealing layer 181 may be made of any one organic insulating material of a polyacrylates resin, an epoxy resin, a phenolic resin, a polyamides resin, a polyimides resin, an unsaturated polyesters resin, a polyphenyleneethers resin, a polyphenylenesulfides resin, and benzocyclobutene (BCB).

The second sealing layer 182 may be made of any one inorganic insulating material of silicon nitride, silicon oxide, and silicon oxynitride.

FIG. 9 illustrates the sealing structure 18 having the structure in which the first sealing layer 181 and the second sealing layer 182 are stacked, but this is only an example. For example, the sealing structure 18 according to an embodiment may include a single insulating layer or three or more insulating layers.

As described above, the display panel 10 according to an embodiment includes the phase adjusting layer 141, the reflected light absorbing layer 142, the black matrix layer 161, and the reflection adjusting layer 162, and thus, may reduce the outside light reflection even though it does not include a polarizing plate. Therefore, a decrease in light emission efficiency due to the polarizing plate may be prevented, and thus, a display quality may be increased.

Next, modified examples of an embodiment will be described.

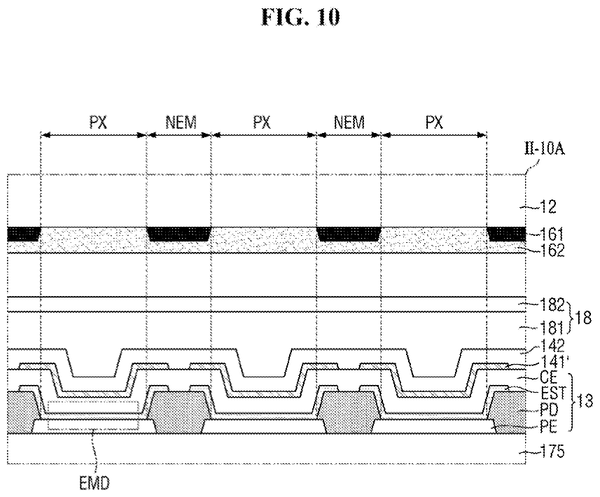

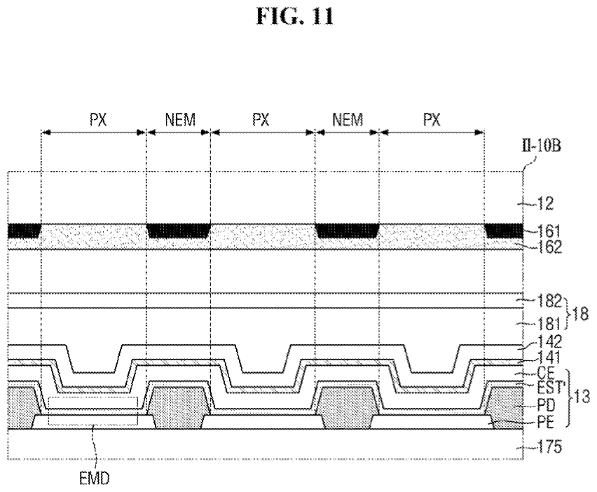

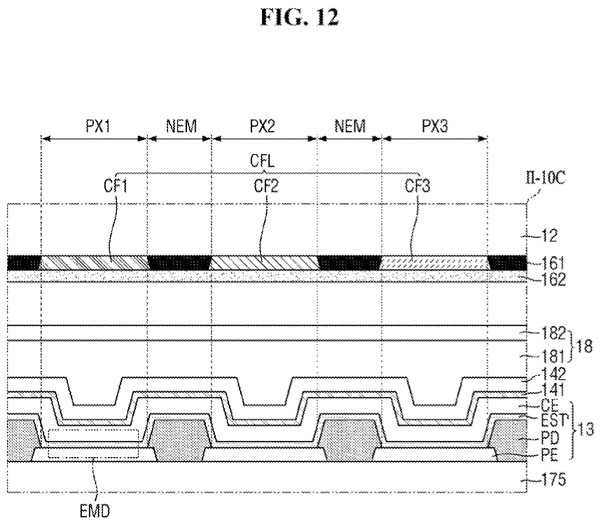

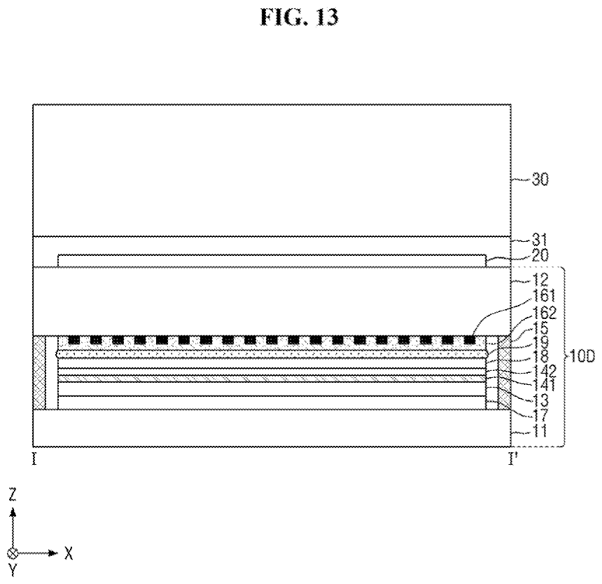

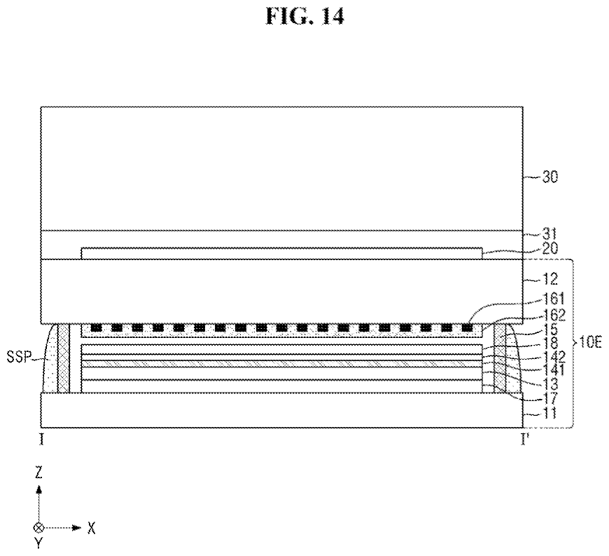

FIG. 10 is an enlarged view illustrating portion II of FIG. 3 according to a first embodiment. FIG. 11 is an enlarged view illustrating portion II of FIG. 3 according to a second embodiment. FIG. 12 is an enlarged view illustrating portion 11 of FIG. 3 according to a third embodiment. FIG. 13 is a cross-sectional view taken along line I-I′ of FIG. 2 according to a fourth embodiment. FIG. 14 is a cross-sectional view taken along line I-I′ of FIG. 2 according to a fifth embodiment.

Referring to FIG. 10, a display panel 10A according to a first embodiment is the same as the display panel according to an embodiment illustrated in FIGS. 1 to 9 except that a phase adjusting layer 141′ does not entirely correspond to the plurality of non-emission areas NEM, but corresponds to each of the plurality of pixel areas PX, and an overlapping description of similar or identical elements may thus be omitted below.

According to a first embodiment, the phase adjusting layer 141′ is not disposed in at least a portion of the non-emission areas NEM that do not correspond to the emitting structures EST. Accordingly, only destructive interference of the reflected light RL generated in each of the plurality of pixel areas PX may be induced in the reflected light absorbing layer 142, which may be advantageous in controlling luminance.

Referring to FIG. 11, a display panel 10B according to a second embodiment is the same as the display panel according to an embodiment illustrated in FIGS. 1 to 9 except that an emitting structure EST′ does not correspond to each of the plurality of pixel areas PX, but entirely corresponds to two or more pixel areas PX arranged in parallel in the second direction (X-axis direction), and an overlapping description of similar or identical elements may thus be omitted. For example, the emitting structure EST′ may be disposed in common to extend over at least two adjacent pixel areas PX and non-emission areas NEM.

Referring to FIG. 12, a display panel IOC according to a third embodiment is the same as the display panel according to an embodiment illustrated in FIGS. 1 to 9 except that it further includes a color filter layer CFL disposed on one side of the encapsulation substrate 12 (e.g., an upper side in the Z-axis direction) and corresponding to the plurality of pixel areas PX and an emitting structure EST′ entirely corresponds to two or more pixel areas PX, and an overlapping description of similar or identical elements may thus be omitted below.

In an embodiment, the plurality of pixel areas PX may include a first pixel area PX1 corresponding to a first color, a second pixel area PX2 corresponding to a second color, and a third pixel area PX3 corresponding to a third color. The first pixel area PX1, the second pixel area PX2, and the third pixel area PX3 may be arranged in parallel in the second direction (X-axis direction).

The color filter layer CFL may include a first color filter CF1 corresponding to the first pixel area PX1 and transmitting light of a wavelength region representing the first color, a second color filter CF2 corresponding to the second pixel area PX2 and transmitting light of a wavelength region representing the second color, and a third color filter CF3 corresponding to the third pixel area PX3 and transmitting light of a wavelength region representing the third color.

The color filter layer CFL may be disposed between the black matrix layer 161 on one side of the encapsulation substrate 12.

In addition, the reflection adjusting layer 162 may cover the color filter layer CFL and the black matrix layer 161.

Referring to FIG. 13, a display panel 10D according to a fourth embodiment is the same as the display panel according to an embodiment illustrated in FIGS. 1 to 9 except that it further includes a filling layer 19 filling a space between the sealing structure 18 and the reflection adjusting layer 162 spaced apart from each other (e.g., in the Z-axis direction), and an overlapping description of same or identical elements may thus be omitted below.

The filling layer 19 may be made of a transparent filling material. For example, in an embodiment the filling layer 19 may be made of a Si-based organic material, an epoxy-based organic material, or the like.

Since the emitting array 13 and the like are disposed below the sealing structure 18, the black matrix layer 161 disposed on the reflection adjusting layer 162, and the like, may be supported by such a filling layer 19, an effect of a physical shock on the display panel 10D may be reduced.

Due to adhesiveness of the filling layer 19, the bonding between the support substrate 11 and the encapsulation substrate 12 may become stronger, and penetration of oxygen or moisture into the emitting array 13 may be further prevented.

Referring to FIG. 14, a display panel 10E according to a fifth embodiment is the same as the display panel according to an embodiment illustrated in FIGS. 1 to 9 except that it further includes an auxiliary sealing pattern SSP disposed on a portion of a flank side (e.g., a lateral side in the X-axis direction) of the sealing layer 15 exposed to the outside, and an overlapping description of similar or identical elements may be omitted below.

In an embodiment, the auxiliary sealing pattern SSP may be formed of a portion of a protection pattern for protecting the sealing layer 15 from a process of disposing the black matrix layer 161.

In an embodiment, the protection pattern may be formed of a positive photoresist to facilitate complete removal thereof. Accordingly, the auxiliary sealing pattern SSP may be formed of a hardened positive photoresist.

The auxiliary sealing pattern SSP is disposed on a portion of the flank side of the sealing layer 15 that does not face the emitting array 13, and is exposed to the outside. Permeation of oxygen or moisture through the sealing layer 15 may be further prevented by such an auxiliary sealing pattern SSP.

In an embodiment of the present disclosure, the display panel may include a plurality of the respective features shown in FIGS. 10-14 which are different from the display panel according to an embodiment illustrated in FIGS. 1 to 9.

Next, a method for fabricating a display panel according to an embodiment will be described.

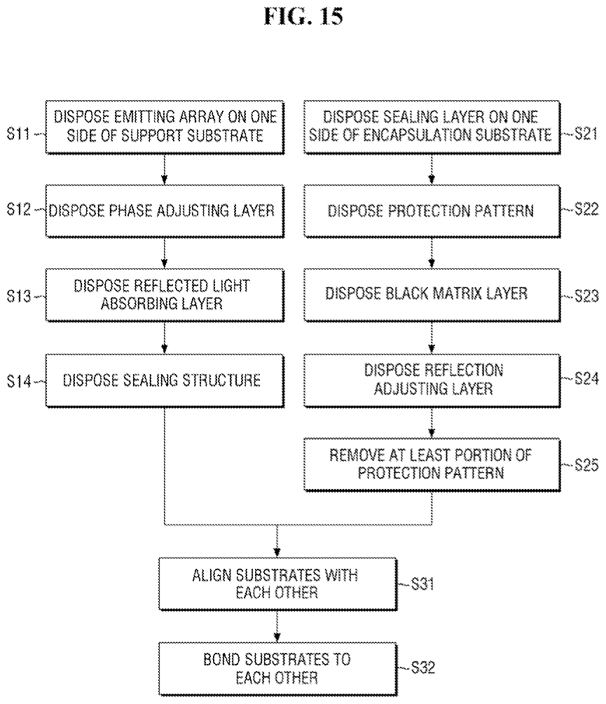

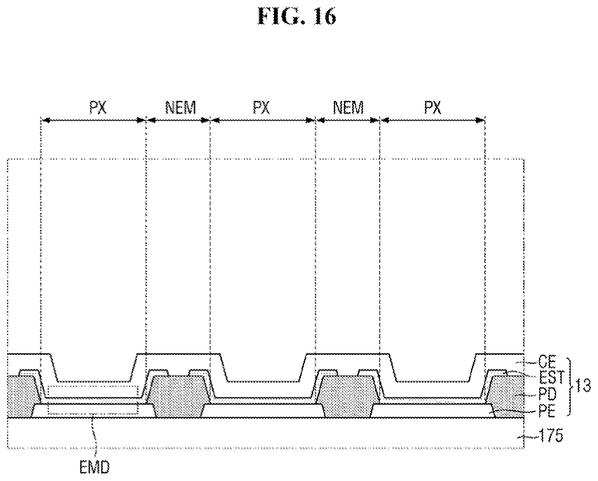

FIG. 15 is a flowchart illustrating a method for fabricating a display panel according to an embodiment. FIGS. 16 to 27 are cross-sectional views illustrating processes for each step of FIG. 15.

Referring to FIG. 15, a method for fabricating a display panel according to an embodiment includes: disposing an emitting array 13 on one side of a support substrate 11 in block S11, the emitting array 13 including a plurality of emitting devices EMD corresponding to a plurality of pixel areas PX, and the support substrate 11 including a display area DA in which the plurality of pixel areas PX are arranged and a non-display area NDA; disposing a phase adjusting layer 141 on the emitting array 13 in block S12, the phase adjusting layer 141 changing a phase of light; disposing a reflected light absorbing layer 142 on the phase adjusting layer 141 in block S13, the reflected light absorbing layer 142 absorbing at least a portion of light reflected from the emitting array 13; disposing a sealing layer 15 on one side of an encapsulation substrate 12 in block S21, the sealing layer 15 surrounding the periphery of the display area DA; disposing a protection pattern covering the sealing layer 15 in block S22; disposing a black matrix layer 161 on one side of the encapsulation substrate 12 in block S23, the black matrix layer 161 corresponding to non-emission areas NEM that are boundaries between the plurality of pixel areas PX in the display area DA; disposing a reflection adjusting layer 162 on one side of the encapsulation substrate 12 in block S24, the reflection adjusting layer 162 covering the black matrix layer 161 and absorbing at least a portion of outside light OL incident from the encapsulation substrate 12; removing at least a portion of the protection pattern in block S25; aligning the support substrate 11 and the encapsulation substrate 12 with each other so that one side of the support substrate 11 and one side of the encapsulation substrate 12 face each other in block S31; and bonding the support substrate 11 and the encapsulation substrate 12 to each other through the sealing layer 15 in block S32.

In addition, the method for fabricating a display panel according to an embodiment may further include, after the disposing of the reflected light absorbing layer 142 in block S13, disposing a sealing structure 18 on the reflected light absorbing layer 142 in block S14.

Referring to FIG. 16, the emitting array 13 including the plurality of emitting devices EMD corresponding to the plurality of pixel areas PX is disposed on one side of the support substrate 11 in block S11.

Referring to FIG. 9, the method for fabricating a display panel according to an embodiment further include, before the disposing of the emitting array 13 in block S11, disposing a circuit array 17 on one side of the support substrate 11, the circuit array 17 including a plurality of pixel driving circuits corresponding to the plurality of pixel areas PX.

For example, the disposing of the circuit array 17 illustrated in an embodiment of FIG. 9 may include: disposing a buffer layer 171 entirely covering one side of the support substrate 11; disposing a semiconductor layer SEL on the buffer layer 171; disposing a gate insulating layer 172 on the buffer layer 171, the gate insulating layer 172 covering the semiconductor layer SEL; disposing a gate electrode GE on the gate insulating layer 172, the gate electrode GE overlapping a channel region of the semiconductor layer SEL; disposing an interlayer insulating layer 173 on the gate insulating layer 172, the interlayer insulating layer 173 covering the gate electrode GE; disposing holes corresponding to portions of a source region and a drain region of the semiconductor layer SEL by patterning the interlayer insulating layer 173 and the gate insulating layer 172; disposing a source electrode SDE1 and a drain electrode SDE2 on the interlayer insulating layer 173; disposing an auxiliary interlayer insulating layer 174 on the interlayer insulating layer 173, the auxiliary interlayer insulating layer 174 covering the source electrode SDE1 and the drain electrode SDE2; and disposing a via layer 175 on the auxiliary interlayer insulating layer 174.

In addition, referring to FIGS. 9 and 16, the disposing of the emitting array 13 in block S11 may include: disposing a plurality of first electrodes PE corresponding to the plurality of pixel areas PX, respectively; disposing a pixel defining layer PD corresponding to the non-emission areas NEM and covering edges of each of the plurality of first electrodes PE; disposing a plurality of emitting structures EST on the plurality of first electrodes PE, respectively; and disposing a second electrode CE on the pixel defining layer PD and the plurality of emitting structures EST.

In this embodiment, each of the plurality of emitting device EMD may have a structure in which the emitting structure EST is interposed between the first electrode PE and the second electrode CE facing each other.

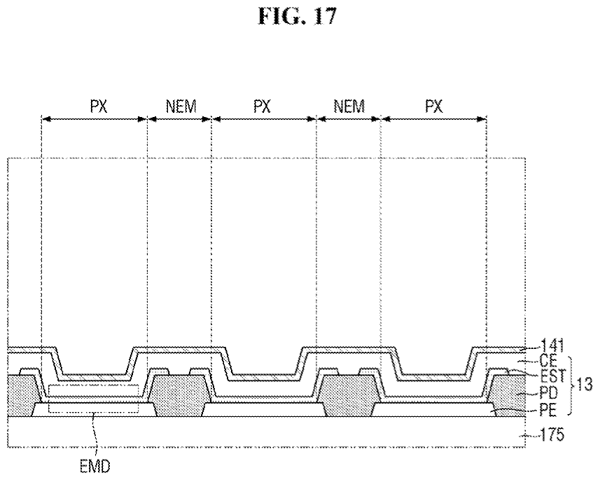

Referring to FIG. 17, the phase adjusting layer 141 is disposed on the emitting array 13 in block S12.

In an embodiment, a thickness of the phase adjusting layer 141 corresponds to a phase difference by the phase adjusting layer 141.

As an example, in an embodiment the phase adjusting layer 141 may be formed to have a thickness at which a phase of the light is delayed by λ/4. In this embodiment a phase difference between the reflected light RL passing through the phase adjusting layer 141 twice and the outside light OL that does not pass through the phase adjusting layer 141 is 180°. For example, the reflected light RL may have an opposite phase to and the same intensity as the outside light OL.

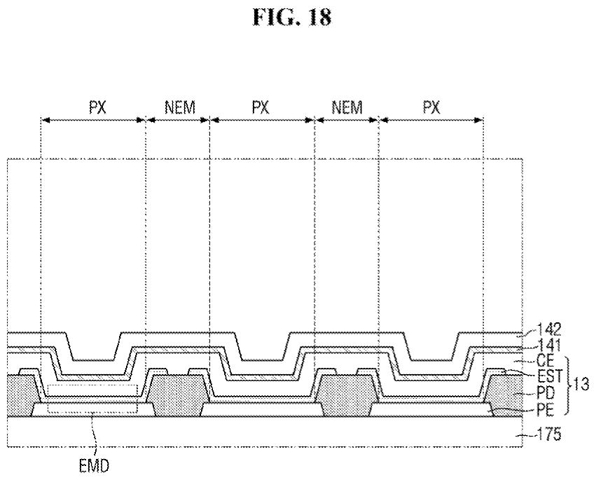

Referring to FIG. 18, the reflected light absorbing layer 142 is disposed on the phase adjusting layer 141 in block S13.

In an embodiment, the reflected light absorbing layer 142 may be made of an inorganic material that has a refractive index of about 1 or more and an absorption coefficient of about 0.5 or more and may be thermally deposited. As an example, in an embodiment the reflected light absorbing layer 142 may be made of at least one of bismuth (Bi) and ytterbium (Yb).

In the reflected light absorbing layer 142, destructive interference between the reflected light RL passing through the phase adjusting layer 141 twice and the outside light OL that does not pass through the phase adjusting layer 141 is induced, such that the reflected light absorbing layer 142 may absorb at least a portion of the reflected light RL.

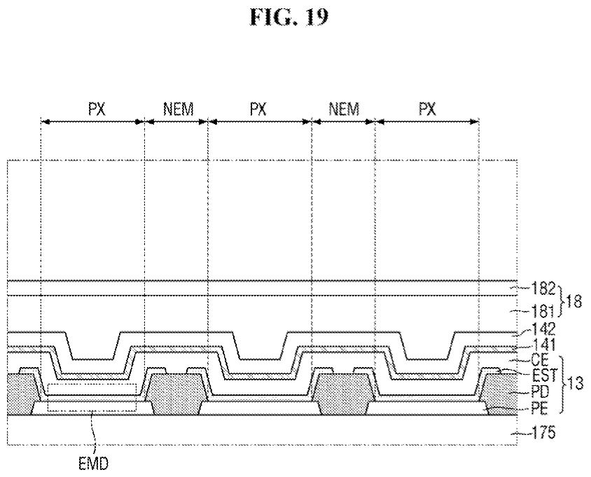

Referring to FIG. 19, the sealing structure 18 is disposed on the reflected light absorbing layer 142 in block S14.

For example, in an embodiment the sealing structure 18 may include a first sealing layer 181 disposed on the reflected light absorbing layer 142 and made of an organic insulating material and a second sealing layer 182 disposed on the first sealing layer 181 and made of an inorganic insulating material.

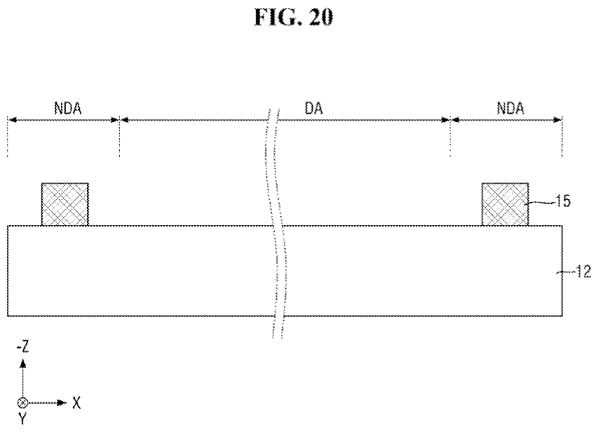

Referring to FIG. 20, after the encapsulation substrate 12 including at least the display area DA is prepared, the sealing layer 15 surrounding the periphery of the display area DA is disposed on one side of an encapsulation substrate 12 in block S21.

In an embodiment, the disposing of the sealing layer 15 in block S21 may include patterning a sealing material on one side of the encapsulation substrate 12 and firing the sealing material to prepare the sealing layer 15.

In this embodiment, the patterning of the sealing material may be performed in a silk screen manner.

In addition, the firing of the sealing material may be performed in a high temperature environment of about 370° C. or higher. In this embodiment, the sealing layer 15 may be prepared by removing an organic material included in the sealing material at a high temperature of about 370° C. or higher.

For example, in an embodiment the sealing layer 15 may be made of an epoxy-based resin.

The sealing layer 15 may be disposed in the non-display area NDA on one side of the encapsulation substrate 12.

The sealing layer 15 may have a thickness in a range of about 3.5 μm to about 6.5 μm.

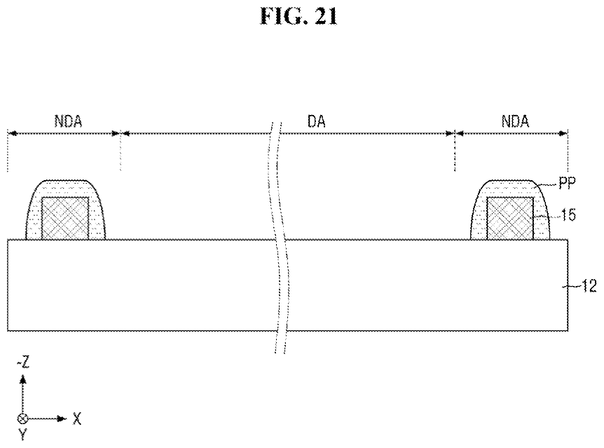

Referring to FIG. 21, the protection pattern PP covering the sealing layer 15 is disposed in block S22.

In an embodiment, the protection pattern PP may be disposed in the non-display area NDA of one side of the encapsulation substrate 12, similar to the sealing layer 15, and may completely surround the sealing layer 15.

In an embodiment, the disposing of the protection pattern PP in block S22 may be performed in a silk screen manner.

In an embodiment, the protection pattern PP may be formed of a positive photoresist.

The positive photoresist is developed when it is exposed to light.

For example, a negative photoresist that is not developed when it is exposed to the light may be completely removed only when the light is completely blocked, and thus, a removal process of the negative photoresist is difficult and it is difficult to increase reliability of the removal process.

On the other hand, in a case of the positive photoresist, a possibility that the positive photoresist will be completely removed by excessive exposure increases, and thus, a removal process of the positive photoresist is relatively easy and reliability of the removal process is relatively high.

Accordingly, in an embodiment, the material of the protection pattern PP is a positive photoresist which prevents the protection pattern PP for protecting the sealing layer 15 from remaining as a foreign material on the sealing layer 15.

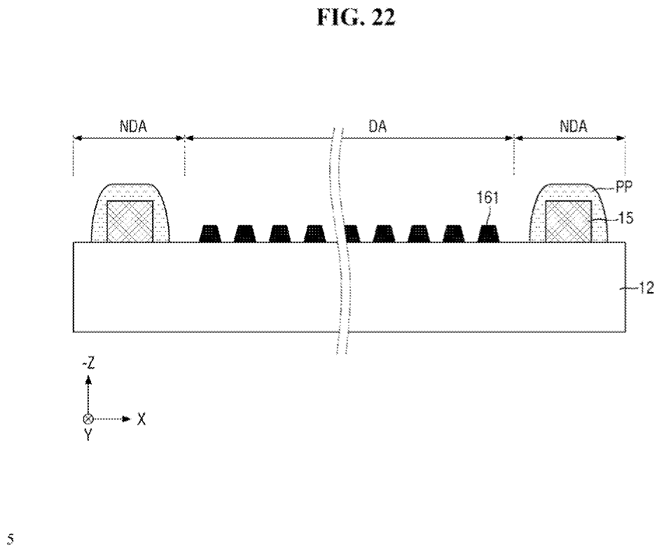

Referring to FIG. 22, in a state in which the sealing layer 15 is covered with the protection pattern PP, the black matrix layer 161 corresponding to the non-emission areas NEM are disposed on one side of the encapsulation substrate 12 in block S23.

In an embodiment, the disposing of the black matrix layer 161 in block S23 may be performed in a slit coating manner or an inkjet printing manner.

In this embodiment, a material of the black matrix layer 161 may become a foreign material while being jetted, but since the sealing layer 15 is in a state in which it is covered with the protection pattern PP, the foreign material made of the material of the black matrix layer 161 may be prevented from being attached to the sealing layer 15.

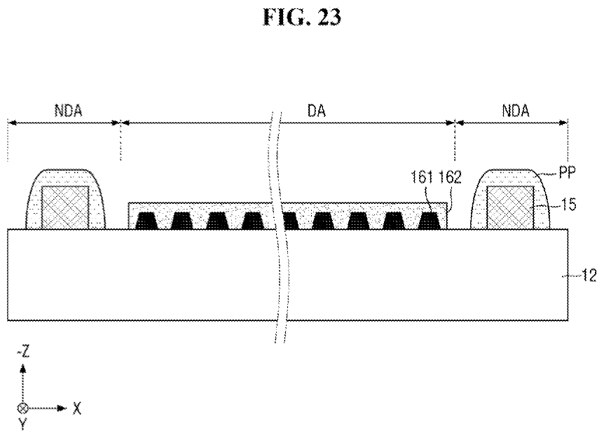

Referring to FIG. 23, in the state in which the sealing layer 15 is covered with the protection pattern PP, the reflection adjusting layer 162 covering the black matrix layer 161 is disposed on one side of the encapsulation substrate 12 in block S24.

The reflection adjusting layer 162 includes a pigment or a dye for absorbing light of a specific wavelength region that is not emitted from the plurality of pixel areas PX among the outside light OL.

For example, the reflection adjusting layer 162 may be made of an organic material including a pigment or a dye absorbing light of a specific wavelength region. In an embodiment, a minimum absorption wavelength region of the pigment or the dye may be a wavelength region in a range of about 490 nm to about 505 nm or a wavelength region of about 585 nm to about 600 nm.

Also during the disposing of the reflection adjusting layer 162 in block S24, the sealing layer 15 is covered with the protection pattern PP, and thus, a material constituting the reflection adjusting layer 162 may be prevented from being attached to the sealing layer 15.

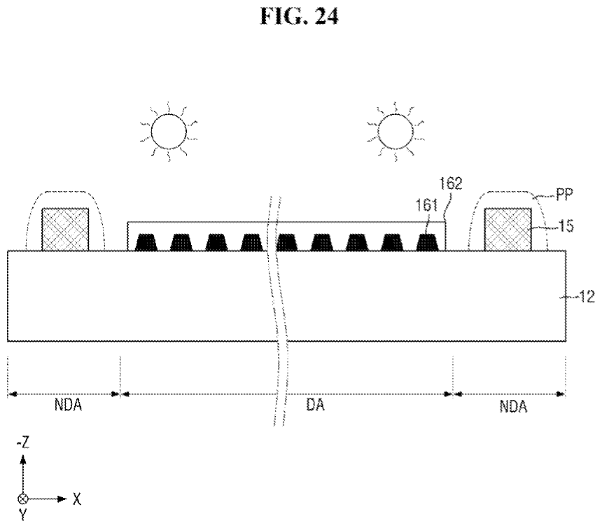

Referring to FIG. 24, after the disposing of the reflection adjusting layer 162 in block S24, at least a portion of the protection pattern PP is removed in block S25.

For example, in an embodiment, in the removing of at least a portion of the protection pattern PP in block S25, the entire protection pattern PP may be completely removed.

In this embodiment, the removing of at least a portion of the protection pattern PP in block S25 may include entirely irradiating one side of the encapsulation substrate 12 with light and developing the protection pattern PP.

For example, in the entire irradiating of one side of the encapsulation substrate 12 with the light, the positive photoresist constituting the protection pattern PP is exposed to the light. In this embodiment, to increase reliability of complete removal of the protection pattern PP, excessive exposure may be performed on the protection pattern PP.

In addition, in the developing of the protection pattern PP, the protection pattern PP may be removed using a material dissolving the positive photoresist.

In this embodiment, a residue of the black matrix layer 161 or a residue of the reflection adjusting layer 162 disposed on the protection pattern PP is removed together with the protection pattern PP.

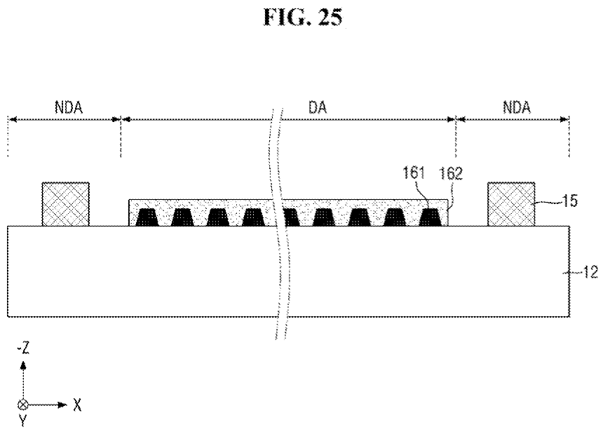

Thereafter, as illustrated in FIG. 25, the protection pattern PP covering the sealing layer 15 may be completely removed. Therefore, the foreign material may not remain on the side of the sealing layer 15.

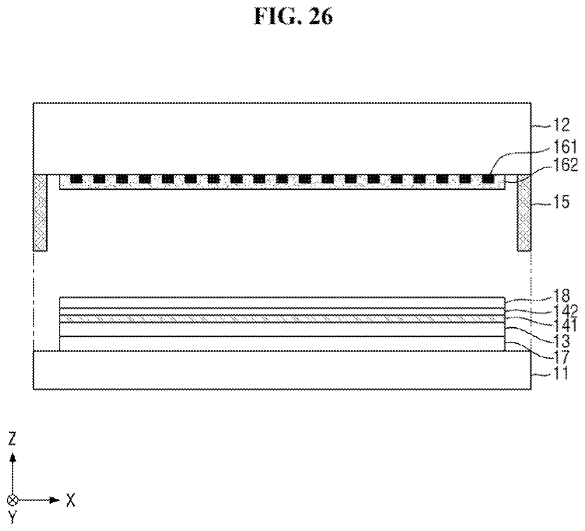

Referring to FIG. 26, the support substrate 11 and the encapsulation substrate 12 are aligned with each other so that one side of the support substrate 11 and one side of the encapsulation substrate 12 face each other in block S31.

In this embodiment, the sealing structure 18 disposed on one side of the support substrate 11 faces the reflection adjusting layer 162 disposed on one side of the encapsulation substrate 12.

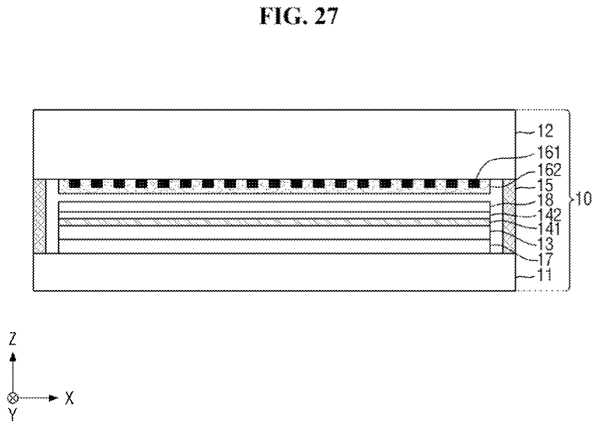

Referring to FIG. 27, the support substrate 11 and the encapsulation substrate 12 are bonded to each other using the sealing layer 15 in block S32.

In this embodiment, the foreign material does not remain on a side of the sealing layer 15, and thus, reliability of the bonding between the support substrate 11 and the encapsulation substrate 12 using the sealing layer 15 may be increased.

For example, according to an embodiment, since the sealing layer 15 is disposed before the black matrix layer 161 vulnerable to a high temperature environment are disposed, the sealing layer 15 may be made of a sealing material fired in the high temperature environment.

In addition, since the black matrix layer 161 are disposed in the state in which the sealing layer 15 is covered with the protection pattern PP, the foreign material made of the material of the black matrix layer 161 may be removed together with the protection pattern PP when the protection pattern PP is removed, and thus, the foreign material may be prevented from being adsorbed on the sealing layer 15.

Therefore, a decrease in an adhesive force of the sealing layer 15 may be prevented, and thus, a bonding defect between the support substrate 11 and the encapsulation substrate 12 may be prevented. Accordingly, a burst defect of the display panel 10 may be decreased, and penetration of oxygen or moisture into the emitting array 13 may be further prevented.

A method for fabricating the display panel 10A according to a first embodiment illustrated in FIG. 10 is the same as the method for fabricating a display panel according to an embodiment illustrated in FIG. 15 except that it further includes disposing a phase adjusting layer 141′ corresponding to each of the plurality of pixel areas PX by patterning the phase adjusting layer on the second electrode CE in the disposing of the phase adjusting layer in block S12, and an overlapping description will thus be omitted.

A method for fabricating the display panel 10B according to a second embodiment illustrated in FIG. 11 is the same as the method for fabricating a display panel according to an embodiment illustrated in FIG. 15 except that an emitting structure EST′ is disposed using a deposition mask in the disposing of the emitting array 13 in block S11, and an overlapping description will thus be omitted below.

A method for fabricating the display panel IOC according to a third embodiment illustrated in FIG. 12 is the same as the method for fabricating a display panel according to an embodiment illustrated in FIG. 15 except that it further includes, before the disposing of the reflection adjusting layer 162 in block S24, disposing a color filter layer CFL on one side of the encapsulation substrate 12, and an overlapping description will thus be omitted.

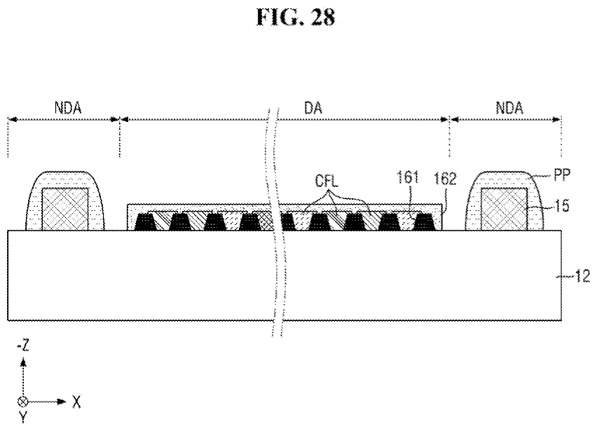

FIG. 28 is a cross-sectional view illustrating some processes of a method for fabricating a display panel illustrated in FIG. 12.

Referring to FIG. 28, in the state in which the sealing layer 15 is covered with the protection pattern PP, the color filter layer CFL corresponding to the plurality of pixel areas PX is disposed on one side of the encapsulation substrate 12.

In this embodiment, the disposing of the color filter layer CFL may include disposing color filters of each color using deposition masks for each color.

A method for fabricating the display panel 10D according to a fourth embodiment illustrated in FIG. 13 is the same as the method for fabricating a display panel according to an embodiment illustrated in FIG. 15 except that it further includes, before the aligning of the support substrate 11 and the encapsulation substrate 12 with each other in block S31, disposing a filling material on at least one of one side of the support substrate 11 and one side of the encapsulation substrate 12, and a filling layer 19 is disposed by widely spreading the filling material in the bonding of the support substrate 11 and the encapsulation substrate 12 to each other in block S32, and an overlapping description will thus be omitted.

A method for fabricating the display panel 10E according to a fifth embodiment illustrated in FIG. 14 is the same as the method for fabricating a display panel according to an embodiment illustrated in FIG. 15 except that a light shield mask is used in the removing of at least a portion of the protection pattern PP in block S25, and an overlapping description will thus be omitted.

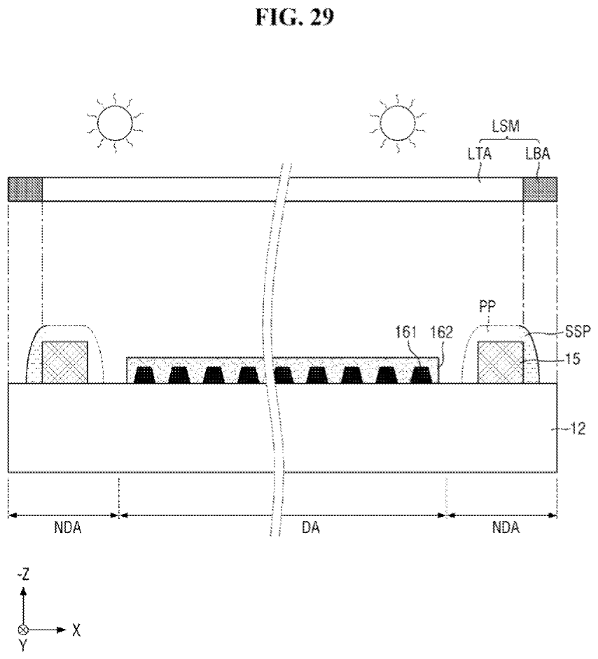

FIG. 29 is a cross-sectional view illustrating some processes of a method for fabricating a display panel illustrated in FIG. 14.

Referring to FIG. 29, the removing of at least a portion of the protection pattern PP in block S25 in the method for fabricating the display panel 10E according to a fifth embodiment may include disposing a light shield mask LSM including a light blocking area LBA corresponding to a portion of a flank side of the sealing layer 15 exposed to the outside, entirely irradiating one side of the encapsulation substrate 12 with light, and developing the protection pattern PP.

The light shield mask LSM may include the light blocking area LBA corresponding to a portion of the flank side of the sealing layer 15 adjacent to an edge of the encapsulation substrate 12 and exposed to the outside and a light transmitting area LTA corresponding to an area other than the light blocking area LBA on one side of the encapsulation substrate 12. In an embodiment, the light blocking area LBA may correspond to an area between the edge of the encapsulation substrate 12 and the light transmitting area LTA and may have a shape of a frame surrounding the light transmitting area LTA.

In addition, in the developing of the protection pattern PP, a portion of the protection pattern PP corresponding to the light shield mask LBM remains, such that an auxiliary sealing pattern SSP disposed on a portion of the flank side of the sealing layer 15 exposed to the outside may be prepared.

However, embodiments of the present disclosure and aspects thereof are not limited to the ones set forth herein.

What is claimed is:

1. A display panel comprising:
a support substrate including a display area having a plurality of pixel areas for displaying an image and a non-display area disposed around the display area;
an encapsulation substrate facing a first side of the support substrate;
an emitting array disposed on the first side of the support substrate, the emitting array including a plurality of emitting devices corresponding to the plurality of pixel areas;
a phase adjusting layer disposed on the emitting array, the phase adjusting layer changing a phase of light;
a reflected light absorbing layer disposed on the phase adjusting layer, the reflected light absorbing layer absorbing at least a portion of light reflected from the emitting array;
a sealing layer disposed in the non-display area between the support substrate and the encapsulation substrate, the sealing layer bonding the support substrate and the encapsulation substrate to each other; and
a black matrix layer disposed on a first side of the encapsulation substrate facing the support substrate and corresponding to non-emission areas that are boundaries between the plurality of pixel areas.

2. The display panel of claim 1, wherein:
the phase adjusting layer delays the phase of light by λ/4;
a first portion of outside light incident from the encapsulation substrate passes through the reflected light absorbing layer and the phase adjusting layer and is reflected by the emitting array to become reflected light passing through the phase adjusting layer again and directed towards the encapsulation substrate;
the reflected light and the outside light have opposite phases to each other, and
the reflected light absorbing layer absorbs at least a portion of the reflected light based on destructive interference between the reflected light and the outside light.

3. The display panel of claim 2, wherein the reflected light absorbing layer is made of an inorganic material having a refractive index greater than or equal to about 1 and an absorption coefficient greater than or equal to about 0.5.

4. The display panel of claim 3, wherein the reflected light absorbing layer is composed of at least one compound selected from bismuth (Bi) and ytterbium (Yb).

5. The display panel of claim 2, further comprising a reflection adjusting layer disposed on the first side of the encapsulation substrate, the reflection adjusting layer covers the black matrix layer and absorbs a second portion of the outside light that is different from the first portion of the outside light.

6. The display panel of claim 5, wherein the reflection adjusting layer is composed of an organic material including a dye or a pigment.

7. The display panel of claim 6, wherein a minimum absorption wavelength region of the dye or the pigment is a wavelength region in a range of about 490 nm to about 505 nm or a wavelength region in a range of about 585 nm to about 600 nm.

8. The display panel of claim 5, further comprising a sealing structure disposed on the reflected light absorbing layer.

9. The display panel of claim 8, wherein:
the sealing structure and the reflection adjusting layer are spaced apart from each other; and
the display panel further includes a filling layer filling a space between the sealing structure and the reflection adjusting layer.

10. The display panel of claim 2, wherein the emitting array includes:
a plurality of first electrodes corresponding to the plurality of pixel areas;
a pixel defining layer corresponding to the non-emission areas and covering edges of each of the plurality of first electrodes;
a plurality of emitting structures disposed on the plurality of first electrodes, respectively; and
a second electrode disposed on the pixel defining layer and the plurality of emitting structures,
each of the plurality of emitting devices has a structure in which each of the plurality of emitting structures is interposed between each of the plurality of first electrodes and the second electrode, and
the phase adjusting layer is disposed on the second electrode.

11. The display panel of claim 2, further comprising an auxiliary sealing pattern disposed on a portion of a flank side of the sealing layer exposed to the outside.

12. The display panel of claim 11, wherein the auxiliary sealing pattern is formed of a hardened positive photoresist.

13. A display apparatus comprising:
a display panel including a display area having a plurality of pixel areas for displaying an image;
a touch sensing unit disposed on the display panel; and
a protection substrate attached to the display panel through an adhesive layer covering the touch sensing unit,
wherein the display panel includes:
a support substrate including the display area and a non-display area disposed around the display area,
an encapsulation substrate facing a first side of the support substrate;
an emitting array disposed on the first side of the support substrate, the emitting array including a plurality of emitting devices corresponding to the plurality of pixel areas;
a phase adjusting layer disposed on the emitting array, the phase adjusting layer changing a phase of light;
a reflected light absorbing layer disposed on the phase adjusting layer, the reflected light absorbing layer absorbing at least a portion of light reflected from the emitting array;
a sealing layer disposed in the non-display area between the support substrate and the encapsulation substrate, the sealing layer bonding the support substrate and the encapsulation substrate to each other;
a black matrix layer disposed on a first side of the encapsulation substrate facing the support substrate and corresponding to non-emission areas that are boundaries between the plurality of pixel areas in the display area; and
a reflection adjusting layer disposed on the first side of the encapsulation substrate, the reflection adjusting layer covers the black matrix layer and absorbs at least a portion of outside light incident from the encapsulation substrate.

14. The display apparatus of claim 13, wherein:
the phase adjusting layer delays the phase of light by λ/4;
a first portion of the outside light incident from the encapsulation substrate passes through the reflected light absorbing layer and the phase adjusting layer, and is reflected by the emitting array to become reflected light passing through the phase adjusting layer again and directed towards the encapsulation substrate,
the reflected light and the outside light have opposite phases to each other; and
the reflected light absorbing layer absorbs at least a portion of the reflected light based on destructive interference between the reflected light and the outside light.

15. The display apparatus of claim 14, wherein the reflected light absorbing layer is made of an inorganic material having a refractive index greater than or equal to about 1 and an absorption coefficient greater than or equal to about 0.5.

16. The display apparatus of claim 15, wherein the reflected light absorbing layer is composed of at least one compound selected from bismuth (Bi) and ytterbium (Yb).

17. The display apparatus of claim 14, wherein:
the reflection adjusting layer is composed of an organic material including a dye or a pigment; and
a minimum absorption wavelength region of the dye or the pigment is a wavelength region in a range of about 490 nm to about 505 nm or a wavelength region in a range of about 585 nm to about 600 nm.

18. The display apparatus of claim 14, wherein the display panel further includes a sealing structure disposed on the reflected light absorbing layer.

19. The display apparatus of claim 18, wherein:
the sealing structure and the reflection adjusting layer are spaced apart from each other; and
the display panel further includes a filling layer filling a space between the sealing structure and the reflection adjusting layer.

20. The display apparatus of claim 14, wherein the display panel further includes an auxiliary sealing pattern disposed on a portion of a flank side of the sealing layer exposed to the outside.

21. The display apparatus of claim 20, wherein the auxiliary sealing pattern is formed of a hardened positive photoresist.

22. The display apparatus of claim 14, wherein:
the touch sensing unit is disposed on a second side of the encapsulation substrate opposite to the first side of the encapsulation substrate, the touch sensing unit includes a plurality of first touch lines extending in a first direction and a plurality of second touch lines extending in a second direction crossing the first direction;
each of the plurality of first touch lines includes first electrode patterns arranged in the first direction;
each of the plurality of second touch lines includes second electrode patterns disposed on a same layer as the first electrode patterns and arranged in the second direction and a contact pattern connecting between the second electrode patterns adjacent to each other in the second direction, and
each of the plurality of first touch lines further includes a bridge pattern disposed on a different layer from the first and second electrode patterns, the bridge pattern crosses the contact pattern and connects between the first electrode patterns adjacent to each other in the first direction.

23. A method for fabricating a display panel comprising:
disposing an emitting array on a first side of a support substrate, the emitting array including a plurality of emitting devices corresponding to a plurality of pixel areas for displaying an image, and the support substrate including a display area having the plurality of pixel areas arranged therein and a non-display area disposed around the display area;
disposing a phase adjusting layer on the emitting array, the phase adjusting layer changing a phase of light;
disposing a reflected light absorbing layer on the phase adjusting layer, the reflected light absorbing layer absorbing at least a portion of light reflected from the emitting array;
disposing a sealing layer on a first side of an encapsulation substrate including at least the display area, the sealing layer surrounding a periphery of the display area;
disposing a protection pattern covering the sealing layer;
disposing a black matrix layer on the first side of the encapsulation substrate, the black matrix layer corresponding to non-emission areas that are boundaries between the plurality of pixel areas in the display area;
disposing a reflection adjusting layer on the first side of the encapsulation substrate, the reflection adjusting layer covering the black matrix layer and absorbing at least a portion of outside light incident from the encapsulation substrate;
removing at least a portion of the protection pattern;
aligning the support substrate and the encapsulation substrate with each other so that the first side of the support substrate and the first side of the encapsulation substrate face each other; and
bonding the support substrate and the encapsulation substrate to each other through the sealing layer.

24. The method for fabricating a display panel of claim 23, wherein:
in the disposing of the protection pattern, the protection pattern is formed of a positive photoresist; and
the removing of at least a portion of the protection pattern includes entirely irradiating the first side of the encapsulation substrate with light and developing the protection pattern.

25. The method for fabricating a display panel of claim 24, wherein:
the removing of at least a portion of the protection pattern further includes, before entirely irradiating the first side of the encapsulation substrate with the light, disposing a light shield mask including a light blocking area corresponding to a portion of a flank side of the sealing layer exposed to the outside; and
in the developing of the protection pattern, a portion of the protection pattern corresponding to the light shield mask remains to form an auxiliary sealing pattern disposed on the portion of the flank side of the sealing layer exposed to the outside.

26. The method for fabricating a display panel of claim 23, wherein the disposing of the sealing layer includes:
patterning a sealing material on the first side of the encapsulation substrate; and
firing the sealing material in a high temperature environment greater than or equal to about 370° C. to prepare the sealing layer.

27. The method for fabricating a display panel of claim 23, wherein in the disposing of the reflected light absorbing layer, the reflected light absorbing layer is composed of an inorganic material having a refractive index greater than or equal to about 1 and an absorption coefficient greater than or equal to about 0.5.

28. The method for fabricating a display panel of claim 27, wherein the reflected light absorbing layer is composed of at least one compound selected from bismuth (Bi) and ytterbium (Yb).

29. The method for fabricating a display panel of claim 23, wherein:
in the disposing of the reflection adjusting layer, the reflection adjusting layer is composed of an organic material including a dye or a pigment; and
a minimum absorption wavelength region of the dye or the pigment is a wavelength region in a range of about 490 nm to about 505 nm or a wavelength region in a range of about 585 nm to about 600 nm.
